(19) United States
(12) Patent Application Publication
(10) Pub. No.: US 2025/0011645 A1
(43) Pub. Date: Jan. 9, 2025

(54) QUANTUM DOT COMPLEX, LIGHT EMITTING ELEMENT INCLUDING THE QUANTUM DOT COMPLEX, AND DISPLAY DEVICE INCLUDING THE QUANTUM DOT COMPLEX

(71) Applicants: Samsung Display Co., LTD., Yongin-si (KR); Hannam University Institute for Industry-Academia Cooperation, Daejeon (KR)

(72) Inventors: WON-JUN PARK, Yongin-si (KR); Dong Ryeol WHANG, Daejeon (KR); SEHUN KIM, Yongin-si (KR); Daeho HWANG, Daejeon (KR)

(21) Appl. No.: 18/662,018

(22) Filed: May 13, 2024

(30) Foreign Application Priority Data
Jul. 6, 2023 (KR) 10-2023-0087889

(51) Int. Cl. C09K 11/02; B82Y 15/00; B82Y 20/00; B82Y 30/00; B82Y 40/00; C09K 11/88; H05B 33/14; H10K 50/115; H10K 50/15; H10K 50/16

(52) U.S. Cl. CPC C09K 11/025; C09K 11/883; H05B 33/14; H10K 50/115; H10K 50/15; H10K 50/16; B82Y 15/00; B82Y 20/00; B82Y 30/00; B82Y 40/00

(57) ABSTRACT

A quantum dot complex includes a quantum dot, a first ligand bonded to a surface of the quantum dot and including a thiol group at an end of the first ligand, and a second ligand different from the first ligand, bonded to a surface of the quantum dot, and including a thiol group at an end of the second ligand and a carboxyl group at an opposite end of the second ligand.

This application claims priority to Korean Patent Application No. 10-2023-0087889, filed on Jul. 6, 2023, the entirety of the contents of which are hereby incorporated by reference.

### BACKGROUND

### 1. Field

The disclosure herein relates to a quantum dot complex, a light-emitting element including the quantum dot complex, and a display device including the quantum dot complex.

### 2. Description of the Related Art

Various types of display devices used for multimedia electronic devices such as televisions, mobile phones, tablets, navigation systems, and game consoles are being developed. Such display devices include so-called self-luminescent display elements which accomplishes display by causing light-emitting materials to emit light.

Among the light-emitting elements, quantum dot light-emitting elements that include quantum dots in an emission layer are capable of providing high color purity, high luminous efficiency, and multicolor light emission. In order to maintain such excellent light emission quality, research is ongoing into emission layer materials and layer-stacking characteristics in regard to adjacent functional layers.

### SUMMARY

The disclosure provides a quantum dot complex having satisfactory quantum yield properties and capable of improving interface properties in regard to adjacent layers.

The disclosure also provides a light-emitting element having satisfactory quantum yield properties and improved reliability resulting from improved properties in regard to adjacent functional layers.

The disclosure also provides a display device including a quantum dot complex and thus having excellent display quality characteristics.

An embodiment of the inventive concept provides a quantum dot complex including a quantum dot, a first ligand bonded to a surface of the quantum dot and including a thiol group at an end of the first ligand, and a second ligand different from the first ligand, bonded to a surface of the quantum dot, and including a thiol group at an end of the second ligand and a carboxyl group at an opposite end of the second ligand.

In an embodiment, the first ligand may include a first head portion including a thiol group, and a first tail portion extending from the first head portion and including an alkyl group.

In an embodiment, the first tail portion may include an alkyl group having 2 carbon atoms to 20 carbon atoms.

In an embodiment, the second ligand may include a second head portion including a thiol group, an end portion spaced apart from the surface of the quantum dot and including a carboxyl group, and a second tail portion disposed between the second head portion and the end portion.

In an embodiment, the second ligand may be represented by Formula 1 below.

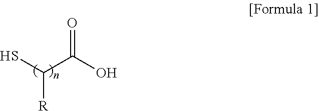

In Formula 1 above, n is an integer of 1 to 20, and R is a hydrogen atom, a deuterium atom, a substituted or unsubstituted thiol group, a substituted or unsubstituted amine group, or a substituted or unsubstituted alkyl group having 1 carbon atom to 10 carbon atoms.

In an embodiment, the second ligand may include at least one of compounds LD1 to LD4 below.

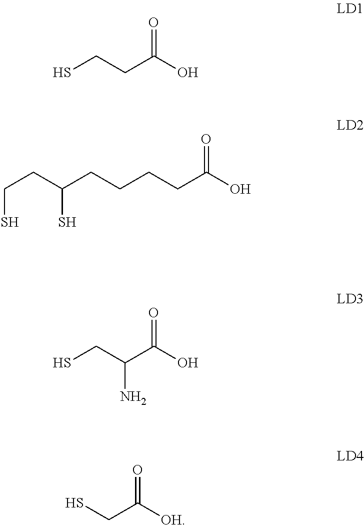 [SMILES: O=C(O)CCS ; O=C(O)CCCCC(S)CCS ; NC(CS)C(=O)O ; O=C(O)CS]

In an embodiment, the first ligand and the second ligand may be at a weight ratio of about 99:1 to about 50:50.

In an embodiment, the quantum dot may include a core and a shell surrounding the core, and the first ligand and the second ligand may each be bonded to a surface of the shell.

In an embodiment, the core may include a first semiconductor nanocrystal, the shell may include a second semiconductor nanocrystal different from the first semiconductor nanocrystal, and the first semiconductor nanocrystal and the second semiconductor nanocrystal may include at least one of a Group II-VI compound, a Group III-VI compound, a Group I-III-VI compound, a Group III-V compound, a Group III-II-V compound, a Group IV-VI compound, a Group IV element, and a Group IV compound.

In an embodiment, the quantum dot may include two or more elements of Group II and Group VI elements, excluding Cd.

In an embodiment, the quantum dot may include ZnSeTe.

In an embodiment, the quantum dot complex may absorb light in a range of about 300 nanometers (nm) to about 450 nm.

In an embodiment of the inventive concept, a light-emitting element includes a first electrode, a second electrode facing the first electrode, an emission layer disposed between the first electrode and the second electrode and including a quantum dot complex, and a functional layer disposed at least one of between the emission layer and the first electrode or between the emission layer and the second electrode, wherein the quantum dot complex includes a quantum dot, a first ligand bonded to a surface of the quantum dot and including a thiol group at an end of the first ligand, and a second ligand different from the first ligand, bonded to a surface of the quantum dot, and including a thiol group at an end of the second ligand and a carboxyl group at an opposite end of the second ligand.

In an embodiment, the first ligand may include a first head portion including a thiol group, and a first tail portion extending from the first head portion and including an alkyl group, and the second ligand may include a second head portion including a thiol group, an end portion spaced apart from the surface of the quantum dot and including a carboxyl group, and a second tail portion disposed between the second head portion and the end portion.

In an embodiment, the second ligand may be represented by Formula 1 below.

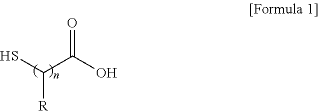

In Formula 1 above, n is an integer of 1 to 20, and R is a hydrogen atom, a deuterium atom, a substituted or unsubstituted thiol group, a substituted or unsubstituted amine group, or a substituted or unsubstituted alkyl group having 1 carbon atom to 10 carbon atoms.

In an embodiment, the second ligand may include at least one of compounds LD1 to LD4 below.

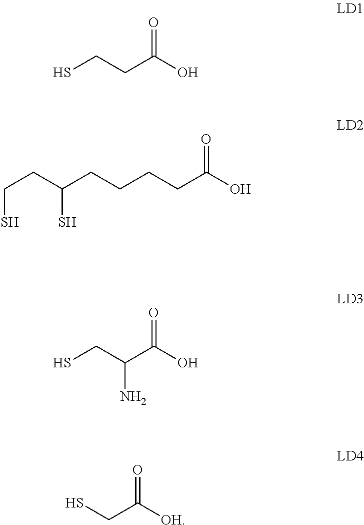 [SMILES: O=C(O)CCS ; O=C(O)CCCCC(S)CCS ; NC(CS)C(=O)O ; O=C(O)CS]

In an embodiment, the functional layer may include a first functional layer disposed between the first electrode and the emission layer, and a second functional layer disposed between the emission layer and the second electrode, wherein any one of the first functional layer and the second functional layer may be a hole transport region, and a remaining one of the first functional layer and the second functional layer may be an electron transport region.

In an embodiment, the functional layer may include a hole transport region disposed below the emission layer, and an electron transport region disposed above the emission layer, the electron transport region may be formed from a common layer composition including an electron transport material and an organic solvent, and a contact angle of the organic solvent with respect to the emission layer may be 15° or less.

In an embodiment of the inventive concept, a display device includes a circuit layer, and a display element layer disposed on the circuit layer and including a light-emitting element and a pixel defining layer in which a pixel opening is defined, wherein the light-emitting element includes a first electrode, a second electrode facing the first electrode, an emission layer disposed between the first electrode and the second electrode and including a quantum dot complex, and a functional layer disposed at least one of between the emission layer and the first electrode or between the emission layer and the second electrode, wherein the quantum dot complex includes a quantum dot, a first ligand bonded to a surface of the quantum dot and including a thiol group at an end of the first ligand, and a second ligand different from the first ligand, bonded to a surface of the quantum dot, and including a thiol group at an end of the second ligand and a carboxyl group at an opposite end of the second ligand.

In an embodiment, the first ligand may include a first head portion including a thiol group, and a first tail portion extending from the first head portion and including an alkyl group, and the second ligand may include a second head portion including a thiol group, an end portion spaced apart from the surface of the quantum dot and including a carboxyl group, and a second tail portion disposed between the second head portion and the end portion.

In an embodiment, the second ligand may be represented by Formula 1 below.

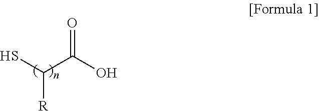

In Formula 1 above, n is an integer of 1 to 20, and R is a hydrogen atom, a deuterium atom, a substituted or unsubstituted thiol group, a substituted or unsubstituted amine group, or a substituted or unsubstituted alkyl group having 1 carbon atom to 10 carbon atoms.

In an embodiment, the second ligand may include at least one of compounds LD1 to LD4 below.

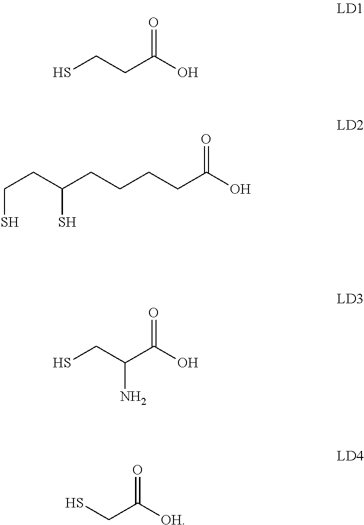 [SMILES: O=C(O)CCS ; O=C(O)CCCCC(S)CCS ; NC(CS)C(=O)O ; O=C(O)CS]

In an embodiment, the functional layer may include a first functional layer disposed between the first electrode and the emission layer, and a second functional layer disposed between the emission layer and the second electrode, wherein any one of the first functional layer and the second functional layer may be a hole transport region, and a remaining one of the first functional layer and the second functional layer may be an electron transport region.

In an embodiment, the emission layer may be disposed in the pixel opening, and the functional layer may be a common layer overlapping the emission layer and the pixel defining layer.

In an embodiment, the light-emitting element may include a first light-emitting element including a first emission layer that emits blue light, a second light-emitting element including a second emission layer that emits green light, and a third light-emitting element including a third emission layer that emits red light, and at least one of the first emission layer, the second emission layer, or the third emission layer may include the quantum dot complex.

### BRIEF DESCRIPTION OF THE DRAWINGS

The accompanying drawings are included to provide a further understanding of the inventive concept, and are incorporated in and constitute a part of this specification. The drawings illustrate embodiments of the inventive concept and, together with the description, serve to explain principles of the inventive concept.

### In the Drawings:

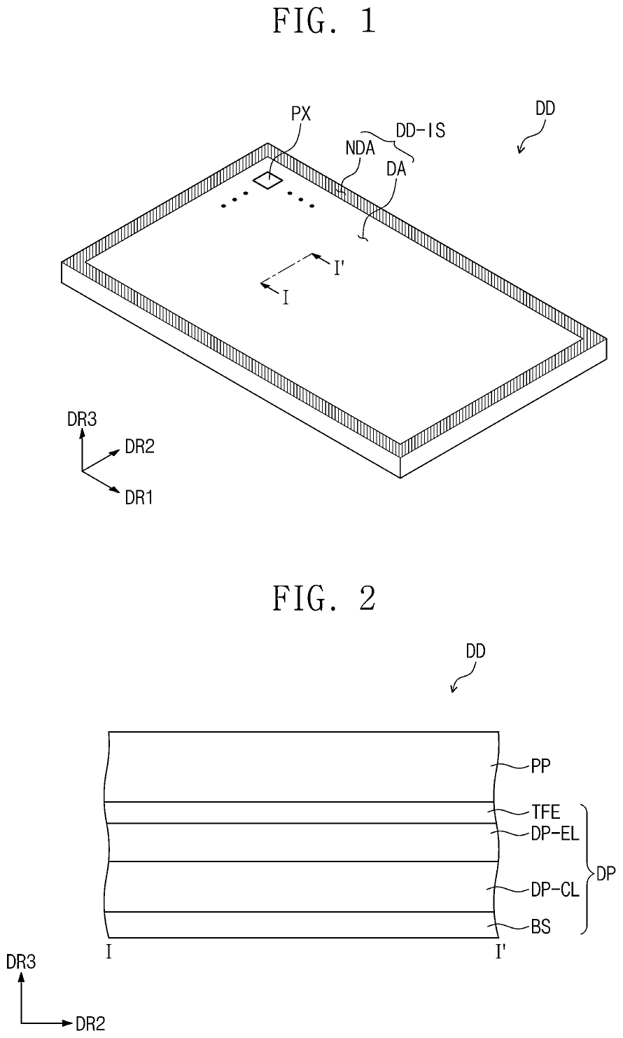

FIG. 1 is a perspective view showing a display device of an embodiment;

FIG. 2 is a cross-sectional view showing a portion corresponding to line I-I′ of FIG. 1;

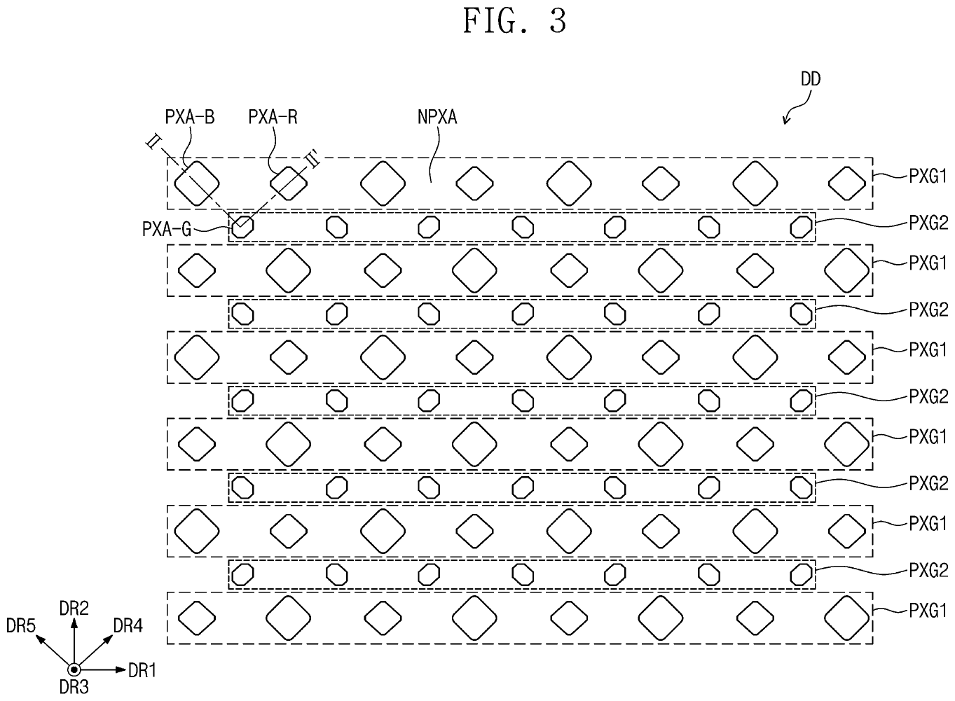

FIG. 3 is a plan view showing a display device of an embodiment;

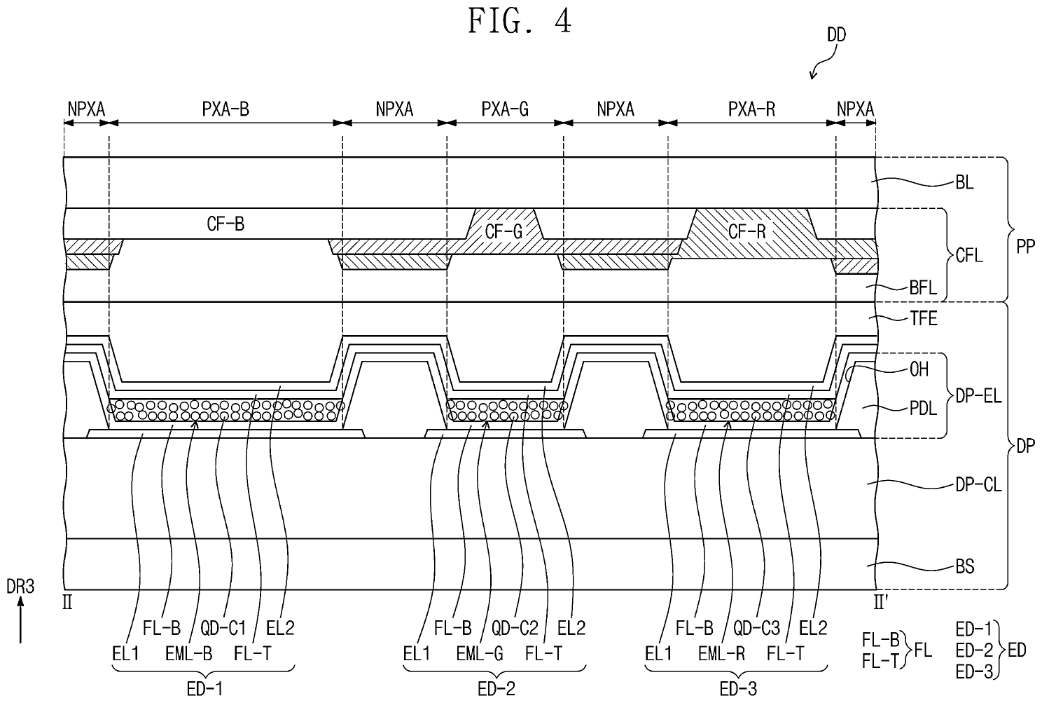

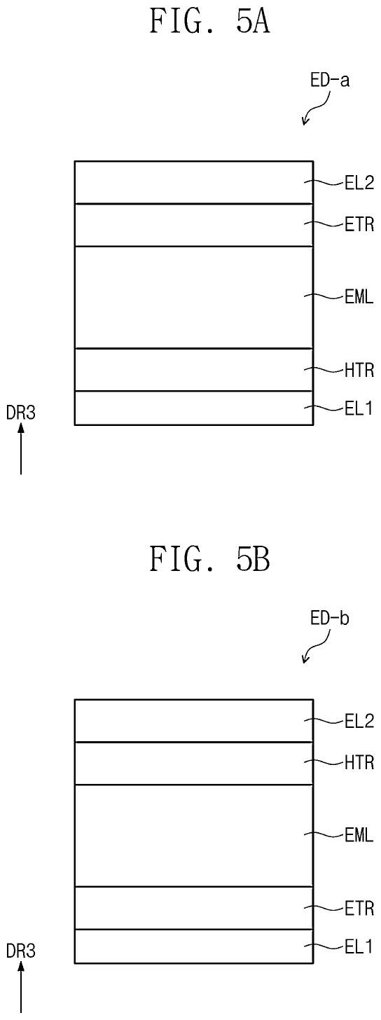

FIG. 4 is a cross-sectional view showing a portion corresponding to line II-II′ of FIG. 3;

FIG. 5A is a cross-sectional view showing a light-emitting element of an embodiment;

FIG. 5B is a cross-sectional view showing a light-emitting element of an embodiment;

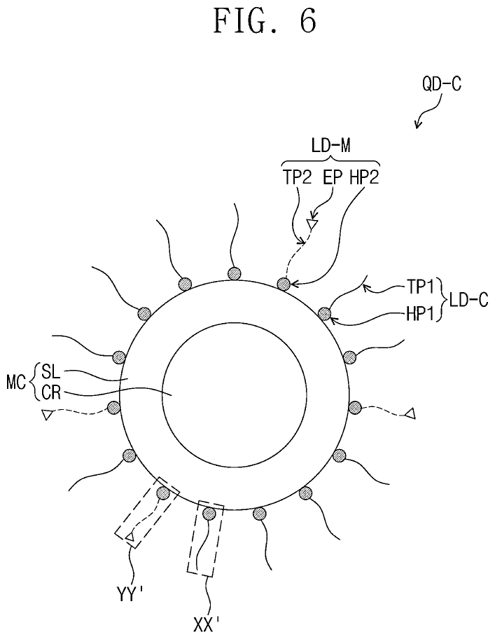

FIG. 6 is a view schematically showing a structure of a quantum dot complex of an embodiment;

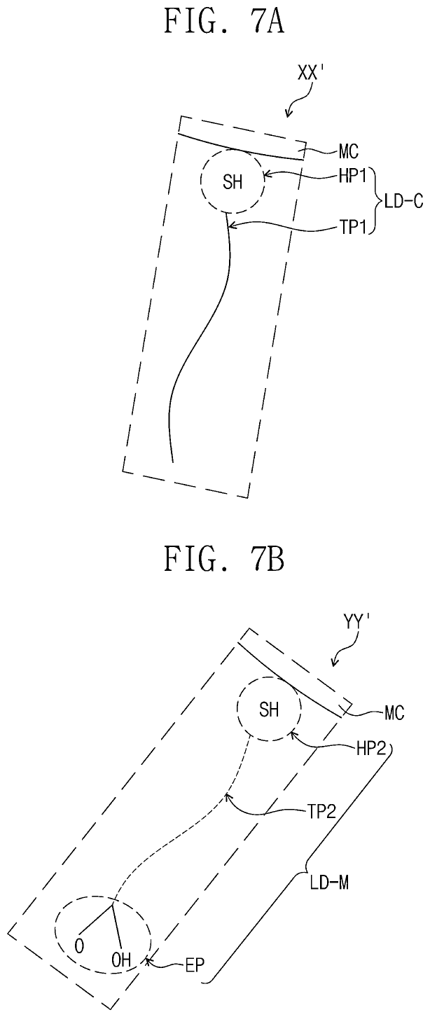

FIG. 7A is a schematic view showing an embodiment of an enlarged portion of a quantum dot complex;

FIG. 7B is a schematic view showing an embodiment of an enlarged portion of a quantum dot complex;

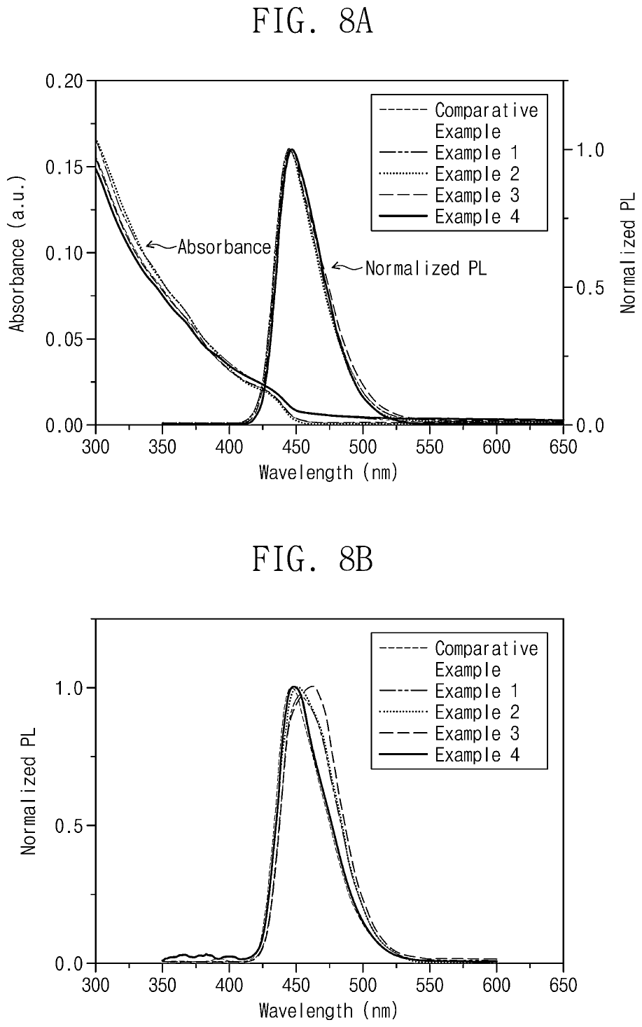

FIG. 8A is a view showing the optical properties and luminous properties of a solution including a quantum dot complex of an embodiment; and

FIG. 8B is a view showing the luminous properties of a film including a quantum dot complex of an embodiment.

### DETAILED DESCRIPTION

The disclosure may be modified in many alternate forms, and thus illustrative embodiments will be exemplified in the drawings and described in detail. It should be understood, however, that it is not intended to limit the disclosure to the particular forms disclosed, but rather, is intended to cover all modifications, equivalents, and alternatives falling within the spirit and scope of the disclosure.

It will be understood that when an element (or a region, a layer, a portion, or the like) is referred to as “being on”, “connected to” or “coupled to” another element, it may be directly disposed on, connected or coupled to the other element, or intervening elements may be disposed therebetween.

Like reference numerals refer to like elements. In addition, in the drawings, the thickness, the ratio, and the dimensions of elements are exaggerated for an effective description of technical contents. The term “and/or,” includes all combinations of one or more of which associated configurations may define.

It will be understood that, although the terms first, second, etc. may be used herein to describe various elements, these elements should not be limited by these terms. These terms are only used to distinguish one element from another element. For example, a first element may be referred to as a second element, and similarly, a second element may be referred to as a first element without departing from the teachings of the present disclosure. The singular forms are intended to include the plural forms as well, unless the context clearly indicates otherwise.

Also, terms of “below”, “on lower side”, “above”, “on upper side”, or the like may be used to describe the relationships of the components shown in the drawings. The terms are used as a relative concept and are described with reference to the direction indicated in the drawings.

It should be understood that the terms “comprise”, or “have” are intended to specify the presence of stated features, integers, steps, operations, elements, components, or combinations thereof in the disclosure, but do not preclude the presence or addition of one or more other features, integers, steps, operations, elements, components, or combinations thereof.

As used herein, the term “Group” refers to a group the IUPAC periodic table of elements.

As used herein, “Group II” may include Group IIA elements and Group IIB elements. For example, the Group II elements may be magnesium (Mg) or zinc (Zn), but are not limited thereto.

As used herein, “Group III” may include Group IIIA elements and Group IIIB elements. For example, the Group III elements may be aluminum (Al), indium (In), gallium (Ga), or titanium (Ti), but are not limited thereto.

As used herein, “Group V” may include Group VA elements and Group VB elements. For example, the Group V elements may be phosphorus (P), arsenic (As), or antimony (Sb), but are not limited thereto.

As used herein, “Group VI” may include Group VIA elements and Group VIB elements. For example, the Group VI elements may be oxygen (O), sulfur (S), selenium (Se) or tellurium (Te), but are not limited thereto.

As used herein, the term “substituted or unsubstituted” may indicate that one is substituted or unsubstituted with at least one substituent selected from the group consisting of a deuterium atom, a halogen atom, a cyano group, a nitro group, an amine group, a silyl group, oxy group, thio group, sulfinyl group, sulfonyl group, carbonyl group, a boron group, a phosphine oxide group, a phosphine sulfide group, an alkyl group, an alkenyl group, an alkynyl group, a hydrocarbon ring group, an aryl group, and a heterocyclic group. In addition, each of the substituents presented as an example above may be substituted or unsubstituted. For example, a biphenyl group may be interpreted as an aryl group or as a phenyl group substituted with a phenyl group.

As used herein, an alkyl group may be linear or branched. The number of carbon atoms in the alkyl group may be 1 to 60, 1 to 50, 1 to 30, 1 to 20, 1 to 10, or 1 to 6. Examples of the alkyl group may include a methyl group, an ethyl group, an n-propyl group, an isopropyl group, an n-butyl group, a s-butyl group, a t-butyl group, an i-butyl group, a 2-ethylbutyl group, a 3,3-a dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, or the like, but are not limited thereto.

Herein, the number of carbon atoms in an amine group is not particularly limited, but may be 1 to 30, 1 to 20, or 1 to 10. The amine group may include an alkyl amine group and an aryl amine group. Examples of the amine group include a methylamine group, a dimethylamine group, a phenylamine group, a diphenylamine group, a naphthylamine group, a 9-methyl-anthracenylamine group, or the like, but are not limited thereto.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within ±30%, 20%, 10%, 5% of the stated value, for example.

Unless otherwise defined, all terms (including technical and scientific terms) used herein have the same meaning as commonly understood by one of ordinary skill in the art to which the disclosure pertains. Also, terms, such as those defined in commonly used dictionaries, should be interpreted as having a meaning that is consistent with their meaning in the context of the relevant art and should not be interpreted in an idealized or overly formal sense unless expressly so defined herein.

Hereinafter, a quantum dot complex, a light-emitting element, and a display device in an embodiment of the inventive concept will be described with reference to the accompanying drawings.

FIG. 1 is a perspective view showing an embodiment of a display device. A display device DD may be a device activated according to electrical signals. In an embodiment, the display device DD may be a large-sized device such as televisions, monitors, or outdoor billboards, for example. In addition, the display device DD may be a small- and medium-sized device such as personal computers, laptop computers, personal digital terminals, car navigation systems, game consoles, smart phones, tablets, and cameras. In addition, these devices are merely provided as embodiments, and other electronic devices may be employed as long as not departing from the inventive concept.

The display device DD may display images (or videos) through a display surface DD-IS. The display surface DD-IS may be parallel to a plane defined by a first direction DR1 and a second direction DR2. The display surface DD-IS may include a display region DA and a non-display region NDA.

In the display region DA, a pixel PX may be disposed. The non-display region NDA may be a portion in which the pixel PX is not disposed. The non-display region NDA may be defined along an edge of the display surface DD-IS. The non-display region NDA may surround the display region DA. However, the inventive concept is not limited thereto, and the non-display region NDA may not be provided, or the non-display region NDA may be disposed only on one side of the display region DA.

FIG. 1 shows the display device DD provided with the flat display surface DD-IS, but the inventive concept is not limited thereto. The display device DD may include a curved display surface or a three-dimensional display surface. The three-dimensional display surface may include a plurality of display regions indicating different directions.

FIG. 1 and the following drawings show first to third directional axes DR1 to DR3, and directions indicated by the first to third directional axes DR1, DR2, and DR3 described herein are relative concepts, and may thus be changed to other directions. In addition, the directions indicated by the first to third directional axes DR1, DR2, and DR3 may be described as first to third directions, and the same reference numerals may be used. The first directional axis DR1 and the second directional axis DR2 herein may be perpendicular to each other, and a third directional axis DR3 may be a normal direction to a plane defined by the first directional axis DR1 and the second directional axis DR2. Herein, the term ‘plane’ refers to a plane defined by the first directional axis DR1 and the second directional axis DR2, and the term ‘cross-section’ refers to a plane perpendicular to the plane defined by the first directional axis DR1 and the second directional axis DR2 and parallel to the third directional axis DR3. A thickness direction of the display device DD may be parallel to the third direction DR3 which is a normal direction with respect to the plane defined by the first direction DR1 and the second direction DR2.

An upper surface (or a front surface) and a lower surface (or a rear surface) of members constituting the display device DD herein may be defined with respect to the third direction DR3. More specifically, among the two surfaces facing in the third direction DR3 in one member, the surface relatively adjacent to the display surface DD-IS may be is defined as a front surface (or an upper surface), and the surface relatively spaced apart from the display surface DD-IS may be defined as a rear surface (or a lower surface). In addition, herein, an upper portion (or an upper side) and a lower portion (or a lower side) may be defined with respect to the third direction DR3, and the upper portion (or upper side) mat be defined as a direction closer toward the display surface DD-IS, and the lower portion (or lower side) may be defined as a direction away from the display surface DD-IS.

Herein, when a component is “directly disposed/directly formed” on another component, it indicates that a third component is not disposed between one component and another component. That is, when a component is “directly placed/directly formed” on another component, it indicates that a component is in “contact” with another component.

FIG. 2 is a cross-sectional view showing a portion corresponding to line I-I′ of FIG. 1. FIG. 2 may be a cross-sectional view of an embodiment of a display device.

The display device DD may include a display panel DP and an optical structure layer PP disposed on the display panel DP. The display panel DP may include a display element layer DP-EL. The display element layer DP-EL may include a light-emitting element ED (FIG. 4). In addition, the display panel DP may include an encapsulation layer TFE disposed on the display element layer DP-EL. The encapsulation layer TFE may be directly disposed on the display element layer DP-EL or may be bonded to the display element layer DP-EL through a separate member.

The optical structure layer PP may be disposed on the display panel DP to control reflected light in the display panel DP by external light. The optical structure layer PP may be a reflection reduction layer reducing reflectance by external light. In an embodiment, the optical structure layer PP may include a polarizing film including a phase retarder and/or a polarizer, multi-layered reflection layers that induces destructive interference of reflected light, or color filters disposed corresponding to the pixel arrangement and light-emitting color of the display panel DP, for example. When the optical structure layer PP includes the color filters, the color filters may be disposed in consideration of the light-emitting colors of pixels included in the display panel DP. In addition, in an embodiment, the optical structure layer PP may not be provided.

The display panel DP may substantially generate images. In the display device DD of an embodiment, the display panel DP may be a light-emitting display panel. In an embodiment, the display panel DP may be a quantum dot light-emitting display panel including a quantum dot light-emitting element. However, the inventive concept is not limited thereto.

The display panel DP may include a base substrate BS, a circuit layer DP-CL disposed on the base substrate BS, and a display element layer DP-EL disposed on the circuit layer DP-CL.

FIG. 3 is a plan view of an embodiment of a display device. FIG. 4 is a cross-sectional view showing a portion corresponding to line II-II′ of FIG. 3. FIG. 4 may be a cross-sectional view showing a display device of an embodiment.

Referring to FIGS. 3 and 4, the display device DD may include a plurality of light-emitting regions PXA-B, PXA-G, and PXA-R, which are repeatedly arranged throughout the display region DA (FIG. 1). The display device DD of an embodiment may include first to third light-emitting regions PXA-B, PXA-G, and PXA-R, which are distinct from one another. In addition, the display device DD may a peripheral region NPXA disposed around the first to third light-emitting regions PXA-B, PXA-G, and PXA-R. The peripheral region NPXA sets boundaries between the first to third light-emitting regions PXA-B, PXA-G, and PXA-R. The peripheral region NPXA may surround the first to third light-emitting regions PXA-B, PXA-G, and PXA-R. A structure, e.g., a pixel defining layer PDL, that prevents color mixing between the first to third light-emitting regions PXA-B, PXA-G, and PXA-R may be disposed in the peripheral region NPXA.

The pixel defining layer PDL may define light-emitting regions PXA-B, PXA-G, and PXA-R. The light-emitting regions PXA-B, PXA-G, and PXA-R, and the peripheral region NPXA may be separated by the pixel defining layer PDL.

The display panel DP in an embodiment may include a plurality of light-emitting elements ED-1, ED-2, and ED-3, which emit light in different wavelength ranges. The plurality of light-emitting elements ED-1, ED-2, and ED-3 may emit light of different colors. In an embodiment, the display panel DP may include a first light-emitting element ED-1 emitting blue light, a second light-emitting element ED-2 emitting green light, and a third light-emitting element ED-3 emitting red light, for example. However, the inventive concept is not limited thereto, and the first to third light-emitting elements ED-1, ED-2 and ED-3 may emit light in the same wavelength range or at least one of the three may emit light in different wavelength ranges.

The light-emitting regions PXA-B, PXA-G, and PXA-R may each be a region emitting light generated from each of light-emitting elements ED-1, ED-2, and ED-3. FIGS. 3 and 4 show first to third light-emitting regions PXA-B, PXA-G, and PXA-R, which emit blue light, green light, and red light, respectively. In an embodiment, the display device DD of an embodiment may include a first light-emitting region PXA-B emitting blue light, a second light-emitting region PXA-G emitting green light, and a third light-emitting region PXA-R emitting red light, which are separated, for example.

In the display device DD of an embodiment shown in FIGS. 3 and 4, the light-emitting regions PXA-B, PXA-G and PXA-R may have different size of areas according to the color emitted from the emission layers EML-B, EML-G, and EML-R of the light-emitting elements ED-1, ED-2 and ED-3. FIG. 3 shows, in an embodiment, the first to third light-emitting regions PXA-B, PXA-G, and PXA-R having the same planar shape and having different planar areas, but the inventive concept is not limited thereto.

The first light-emitting region PXA-B corresponding to the first light-emitting element ED-1 emitting blue light may have a largest area, and the second light-emitting region PXA-G corresponding to the second light-emitting element ED-2 emitting green light may have a smallest area. However, the inventive concept is not limited thereto, and the first to third light-emitting regions PXA-B, PXA-G, and PXA-R may emit light of colors other than blue light, green light, and red light. In an alternative embodiment, the first to third light-emitting regions PXA-B, PXA-G, and PXA-R may have the same area as each other, or may be provided with area ratios different from what shown in FIG. 3. The areas of the first to third light-emitting regions PXA-B, PXA-G, and PXA-R may be set according to the color of emitted light. In this case, the areas may be areas in a plan view.

The first light-emitting region PXA-B and the third light-emitting region PXA-R may be alternately arranged in the first directional axis DR1 to form a first group PXG1. The second light-emitting region PXA-G may be disposed in the first directional axis DR1 to form a second group PXG2. The first group PXG1 may be spaced apart from the second group PXG2 in the second directional axis DR2. The first group PXG1 and the second group PXG2 may each be provided in plural. The first groups PXG1 and the second groups PXG2 may be alternately arranged in the second directional axis DR2.

One third light-emitting region PXA-R may be spaced apart from one second light-emitting region PXA-G in the direction of a fourth directional axis DR4. One first light-emitting region PXA-B may be spaced apart from one second light-emitting region PXA-G in the direction of a fifth directional axis DR5. The fourth directional axis DR4 may be a direction between the first directional axis DR1 and the second directional axis DR2. The fifth directional axis DR5 may cross the fourth directional axis DR4 and may be inclined with respect to the second directional axis DR2.

The arrangement structure of the light-emitting regions PXA-B, PXA-G and PXA-R is not limited to the arrangement structure shown in FIG. 3. In an embodiment, in the light-emitting regions PXA-B, PXA-G, and PXA-R, the first light-emitting region PXA-B, the second light-emitting region PXA-G, and the third light-emitting region PXA-R may be arranged sequentially and alternately along the first directional axis DR1, for example. In addition, the shapes of the light-emitting regions PXA-B, PXA-G, and PXA-R in a plan view are not limited to what is shown, and may be defined as shapes different from what is shown.

Referring to FIG. 4, the display device DD may include a display panel DP and an optical structure layer PP, which are stacked in the third directional axis DR3. The display panel DP may include a base substrate BS, a circuit layer DP-CL provided on the base substrate BS, and a display element layer DP-EL. The display element layer DP-EL may include a light-emitting element ED disposed between the pixel defining layer PDL or on the pixel defining layer PDL, and an encapsulation layer TFE disposed on the light-emitting element ED.

The base substrate BS may be a member providing a base surface in which the display element layer DP-EL is disposed. The base substrate BS may be a glass substrate, a metal substrate, a plastic substrate, or the like. However, the inventive concept is not limited thereto, and the base substrate BS may be an inorganic layer, an organic layer, or a complex material layer.

The base substrate BS may include a single- or multi-layered structure. In an embodiment, the base substrate BS may include a first synthetic resin layer, a multi-layered or single-layered intermediate layer, and a second synthetic resin layer, which are sequentially stacked, for example. The intermediate layer may be also referred to as a base barrier layer. The intermediate layer may include a silicon oxide (SiOx) layer and an amorphous silicon (a-Si) layer disposed on the silicon oxide layer, but is not particularly limited thereto. In an embodiment, the intermediate layer may include at least one of a silicon oxide layer, a silicon nitride layer, a silicon oxynitride layer, or an amorphous silicon layer, for example. The base substrate BS may be a flexible substrate that may be readily bent or folded.

The first and second synthetic resin layers may each include a polyimide-based resin. In addition, the first and second synthetic resin layers may each include at least one among an acrylic-based resin, a methacrylate-based resin, a polyisoprene-based resin, a vinyl-based resin, an epoxy-based resin, a urethane-based resin, a cellulose-based resin, a siloxane-based resin, a polyamide-based resin, and a perylene-based resin. As used herein, a “component-based” resin may be considered as including a functional group of “component”.

In an embodiment, the circuit layer DP-CL may be disposed on the base substrate BS, and the circuit layer DP-CL may include a plurality of transistors (not shown). The transistors (not shown) may each include a control electrode, an input electrode, and an output electrode. In an embodiment, the circuit layer DP-CL may include a switching transistor and a driving transistor for driving the light-emitting element ED of the display element layer DP-EL, for example.

The display element layer DP-EL may be disposed on the circuit layer DP-CL. The display element layer DP-EL may include a pixel defining layer PDL and first to third light-emitting elements ED-1, ED-2, and ED-3, which are divided by the pixel defining layer PDL. The light-emitting elements ED-1, ED-2, and ED-3 of the display element layer DP-EL may be electrically connected to driving elements of the circuit layer DP-CL, and may thus generate light according to signals provided by the driving elements to display images.

The encapsulation layer TFE may be disposed on the display element layer DP-EL. The encapsulation layer TFE may serve to protect the display element layer DP-EL from moisture, oxygen, and foreign substances such as dust particles. The encapsulation layer TFE may seal the light-emitting elements ED of the display element layer DP-EL. The encapsulation layer TFE may include at least one thin film for improving optical efficiency of the display element layer DP-EL or protecting the display element layer DP-EL. The encapsulation layer TFE may include at least one inorganic layer. The encapsulation layer TFE may include a stack structure in which an inorganic layer, an organic layer, and an inorganic layer are sequentially stacked.

The pixel defining layer PDL may include or consist of a polymer resin. In an embodiment, the pixel defining layer PDL may be formed including a polyacrylate-based resin or a polyimide-based resin, for example. In addition, the pixel defining layer PDL may be formed by further including an inorganic material in addition to the polymer resin. The pixel defining layer PDL may be formed including a light absorbing material, or may be formed including a black pigment or a black dye. The pixel defining layer PDL formed including a black pigment or a black dye may implement a black pixel defining layer. When forming the pixel defining layer PDL, carbon black may be used as a black pigment or a black dye, but the inventive concept is not limited thereto.

In addition, the pixel defining layer PDL may include or consist of an inorganic material. In an embodiment, the pixel defining layer PDL may include or consist of silicon nitride (SiNx), silicon oxide (SiOx), silicon oxynitride (SiOxNy), or the like.

A pixel opening OH may be defined in the pixel defining layer PDL. A portion of a first electrode EL1 may be exposed in the pixel opening OH. Portions corresponding to the first electrode EL1 exposed in the pixel opening OH may be defined as light-emitting regions PXA-B, PXA-G, and PXA-R. However, the inventive concept is not limited thereto.

The pixel defining layer PDL may separate the first to third light-emitting elements ED-1, ED-2, and ED-3. The emission layers EML-B, EML-G, and EML-R of the light-emitting elements ED-1, ED-2 and ED-3 may be disposed and separated in the pixel opening OH defined by the pixel defining layer PDL.

The first to third light-emitting elements ED-1, ED-2, and ED-3 may each include a first electrode EL1, a second electrode EL2 facing the first electrode EL1, emission layers EML-B, EML-G, and EML-R disposed between the first electrode EL1 and the second electrode EL2, and a functional layer FL disposed between the first electrode EL1 and the second electrode EL2. The functional layer FL may be disposed at least one of between the first electrode EL1 and the emission layers EML-B, EML-G, and EML-R or between the emission layers EML-B, EML-G, and EML-R and the second electrode EL2. In an embodiment, the first to third light-emitting elements ED-1, ED-2, and ED-3 may each include a first electrode EL1, a first functional layer FL-B, emission layers EML-B, EML-G, and EML-R, a second functional layer FL-T, and a second electrode EL2, which are sequentially stacked in the third directional axis DR3.

The first electrode EL1 may be exposed in the pixel opening OH of the pixel defining layer PDL. The first electrode EL1 has conductivity. The first electrode EL1 may include or consist of a metal material, a metal alloy or a conductive compound. The first electrode EL1 may be an anode or a cathode. However, the inventive concept is not limited thereto.

In addition, the first electrode EL1 may be a pixel electrode. The first electrode EL1 may be a transmissive electrode, a transflective electrode, or a reflective electrode. The first electrode may include at least one of Ag, Mg, Cu, Al, Pt, Pd, Au, Ni, Nd, Ir, Cr, Li, Ca, LiF, Mo, Ti, W, In, Sn, and Zn, two or more compounds selected therefrom, two or more combinations selected therefrom, or an oxide thereof.

When the first electrode EL1 is the transmissive electrode, the first electrode EL1 may include a transparent metal oxide such as indium tin oxide (“ITO”), indium zinc oxide (“IZO”), zinc oxide (ZnO), and indium tin zinc oxide (“ITZO”). When the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (a stack structure of LiF and Ca), LiF/Al (a stack structure of LiF and Al), Mo, Ti, W, any combinations thereof (e.g., a combination of Ag and Mg). In an alternative embodiment, the first electrode EL1 may have a multilayer structure including a reflective film or a transflective film including or consisting of the above-described materials, and a transparent conductive film including or consisting of ITO, IZO, zinc oxide (ZnO), ITZO, or the like. In an embodiment, the first electrode EL1 may have a three-layer structure of ITO/Ag/ITO, for example, but is not limited thereto. In addition, the first electrode EL1 may include the above-described metal materials, a combination of two or more metal materials selected from the above-described metal materials, or oxides of the above-described metal materials, and the inventive concept is not limited thereto. The first electrode EL1 may have a thickness of about 700 angstroms (Å) to about 10,000 Å. In an embodiment, the first electrode EL1 may have a thickness of 1,000 Å to about 3000 Å, for example.

A second electrode EL2 may be disposed on the first electrode EL1. The second electrode EL2 may be a cathode or an anode. In an embodiment, when the first electrode EL1 is an anode, the second electrode EL2 may be a cathode, and when the first electrode EL1 is a cathode, the second electrode EL2 may be an anode. The second electrode EL2 may be a common electrode. However, the inventive concept is not limited thereto.

The second electrode EL2 may include at least one of Ag, Mg, Cu, Al, Pt, Pd, Au, Ni, Nd, Ir, Cr, Li, Ca, LiF, Mo, Ti, W, In, Sn, and Zn, two or more compounds selected therefrom, two or more combinations selected therefrom, or an oxide thereof.

The second electrode EL2 may be a transmissive electrode, a transflective electrode, or a reflective electrode. When the second electrode EL2 is a transmissive electrode, the second electrode EL2 may include or consist of a transparent metal oxide, e.g., ITO, IZO, zinc oxide (ZnO), ITZO, or the like.

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, or any combinations thereof (e.g., AgMg, AgYb, or MgYb). In an alternative embodiment, the second electrode EL2 may have a multilayer structure including a reflective film or a transflective film including or consisting of the above-described materials, and a transparent conductive film including or consisting of ITO, IZO, zinc oxide (ZnO), ITZO, or the like. In an embodiment, the second electrode EL2 may include the above-described metal materials, a combination of two or more metal materials selected from the above-described metal materials, or oxides of the above-described metal materials, for example.

Although not shown, the second electrode EL2 may be connected with an auxiliary electrode. When the second electrode EL2 is connected with the auxiliary electrode, the resistance of the second electrode EL2 may decrease.

Emission layers EML-B, EML-G, and EML-R may be disposed between the first electrode EL1 and the second electrode EL2. The light-emitting element ED of an embodiment may include quantum dot complexes QD-C1, QD-C2, and QD-C3 of an embodiment in the emission layers EML-B, EML-G, and EML-R. In addition, the display device DD of an embodiment may include the first to third light-emitting elements ED-1, ED-2, and ED-3, and at least one of the first to third light-emitting elements ED-1, ED-2, or ED-3 may include the emission layers EML-B, EML-G, and EML-R including quantum dot complexes QD-C1, QD-C2, and QD-C3.

The quantum dot complexes QD-C1, QD-C2, and QD-C3 of an embodiment may include quantum dots and two different ligands. The quantum dot complexes QD-C1, QD-C2, and QD-C3 of an embodiment include two different ligands and one of the ligands includes a carboxyl group, which is an acid functional group, at a terminal end, and accordingly, surface characteristics of improved compatibility with polar materials may be obtained. Accordingly, the light-emitting element ED of an embodiment may exhibit excellent coating properties and excellent adhesion to the neighboring functional layer FL, thereby showing excellent element characteristics and reliability.

In addition, the display device DD of an embodiment including a plurality of light-emitting elements ED including the quantum dot complexes QD-C1, QD-C2, and QD-C3 in an embodiment may exhibit excellent display quality and reliability resulting from the improved surface characteristics of the quantum dot complexes QD-C1, QD-C2, and QD-C3.

The emission layers EML-B, EML-G, and EML-R may each include a plurality of quantum dot complexes QD-C1, QD-C2, and QD-C3. In an embodiment, the emission layers EML-B, EML-G, and EML-R may emit light of fluorescence. In an embodiment, the quantum dot complexes QD-C1, QD-C2, and QD-C3 may be used as fluorescent dopant materials, for example.

In an embodiment, the first light-emitting element ED-1 may include a first emission layer EML-B including a first quantum dot complex QD-C1, the second light-emitting element ED-2 may include a second emission layer EML-G including a second quantum dot complex QD-C2, and the third light-emitting element ED-3 may include a third emission layer EML-R including a third quantum dot complex QD-C3. In an embodiment, the first quantum dot complex QD-C1 may emit blue light, the second quantum dot complex QD-C2 may emit green light, and the third quantum dot complex QD-C3 may emit red light. However, the inventive concept is not limited thereto, and the first to third quantum dot complexes QD-C1, QD-C2, and QD-C3 may emit light in wavelength ranges other than blue, green, and red.

The quantum dot complexes QD-C1, QD-C2, and QD-C3 each included in the emission layers EML-B, EML-G, and EML-R may be stacked to form a layer. In FIG. 4, the quantum dot complexes QD-C1, QD-C2, and QD-C3 having a circular cross-section are arranged to form two layers, but the inventive concept is not limited thereto. In an embodiment, the arrangement of the quantum dot complexes QD-C1, QD-C2, and QD-C3 may vary depending on the thicknesses of the emission layers EML-B, EML-G, and EML-R, the shapes of the quantum dot complexes QD-C1, QD-C2, and QD-C3 included in the emission layers EML-B, EML-G, and EML-R, the average diameters of the quantum dot complexes QD-C1, QD-C2, and QD-C3, or the like, for example. Specifically, in the emission layers EML-B, EML-G, and EML-R, the quantum dot complexes QD-C1, QD-C2, and QD-C3 may be aligned adjacent to each other to form a single layer, or may be aligned to form a plurality of layers, such as two layers or three layers. In addition, the emission layers EML-B, EML-G, and EML-R may further include light-emitting materials in addition to the quantum dot complexes QD-C1, QD-C2, and QD-C3. In an embodiment, the emission layers EML-B, EML-G, and EML-R may further include fluorescent or phosphorescent dopant materials, or may further include host materials.

In an embodiment, the quantum dot complexes QD-C1, QD-C2, and QD-C3 may include quantum dots and two types of ligands bonded to the quantum dots. The quantum dots constituting the first to third quantum dot complexes QD-C1, QD-C2, and QD-C3 may include or consist of different materials from each other. In an alternative embodiment, unlike what is described above, the first to third quantum dot complexes QD-C1, QD-C2, and QD-C3 may include or consist of the same core material as each other, or two quantum dots selected from the first to third quantum dot complexes QD-C1, QD-C2, and QD-C3 may include or consist of the same core material and a remaining one of the first to third quantum dot complexes QD-C1, QD-C2, and QD-C3 may include or consist of different core materials from each other.

In addition, in an embodiment, the quantum dot complexes QD-C1, QD-C2, and QD-C3 may each include a core and a shell surrounding the core. Accordingly, the quantum dot complexes QD-C1, QD-C2, and QD-C3 may each have a core-shell structure. In an embodiment, the first to third quantum dot complexes QD-C1, QD-C2, and QD-C3 included in the light-emitting elements ED-1, ED-2, and ED-3 may include or consist of different core materials from each other. In an alternative embodiment, the first to third quantum dot complexes QD-C1, QD-C2, and QD-C3 may include or consist of the same core material as each other, or two quantum dots selected from the first to third quantum dot complexes QD-C1, QD-C2, and QD-C3 may include or consist of the same core material and a remaining one of the first to third quantum dot complexes QD-C1, QD-C2, and QD-C3 may include or consist of different core materials from each other.

In an embodiment, the first to third quantum dot complexes QD-C1, QD-C2, and QD-C3 may have different diameters from each other. In an embodiment, the first quantum dot complex QD-C1 used in the first light-emitting element ED-1 emitting light in a relatively short wavelength range may have a relatively smaller average diameter than that of the second quantum dot complex QD-C2 of the second light-emitting element ED-2 and that of the third quantum dot complex QD-C3 of the third light-emitting element ED-3 each emitting light in a relatively long wavelength range. Herein, the average diameter refers to the arithmetic mean of the diameters of a plurality of quantum dot particles. The diameter of the quantum dot particle may be the average value of the width of the quantum dot particle in a cross section.

The relationship of the average diameters of the first to third quantum dot complexes QD-C1, QD-C2, and QD-C3 is not limited to the above limitations. That is, FIG. 4 shows that the first to third quantum dot complexes QD-C1, QD-C2, and QD-C3 are shown to be similar in size from one another, but unlike what is shown, the first to third quantum dot complexes QD-C1, QD-C2, and QD-C3 included in the light-emitting elements ED-1, ED-2, and ED-3 may be different in size.

The physical or chemical properties, such as structure and material, of the quantum dot complexes QD-C1, QD-C2, and QD-C3 in an embodiment will be described in more detail later with reference to FIGS. 6 to 7B.

In the display device DD of an embodiment shown in FIG. 4, although the thicknesses of the emission layers EML-B, EML-G, and EML-R of the first to third light-emitting elements ED-1, ED-2, and ED-3 are shown to be similar to one another, the inventive concept is not limited thereto. In an embodiment, in an embodiment, the thicknesses of the emission layers EML-B, EML-G, and EML-R of the first to third light-emitting elements ED-1, ED-2, and ED-3 may be different from one another.

Any one of a first functional layer FL-B disposed between the first electrode EL1 and the emission layers EML-B, EML-G, and EML-R and a second functional layer FL-T disposed between the emission layers EML-B, EML-G, and EML-R and the second electrode EL2 may be a hole transport region, and a remaining one of the first functional layer FL-B and the second functional layer FL-T may be an electron transport region.

FIGS. 5A and 5B are views each showing an embodiment of a light-emitting element. The structure of light-emitting elements ED-a and ED-b described with reference to FIGS. 5A and 5B may apply to at least one of the first to third light-emitting elements ED-1, ED-2, and ED-3 shown in FIG. 4.

In FIG. 5A, the light-emitting element ED-a of an embodiment may include a first electrode EL1, a hole transport region HTR, an emission layer EML, an electron transport region ETR, and a second electrode EL2, which are sequentially stacked along the third directional axis DR3. In the light-emitting element ED-a of an embodiment, the first electrode EL1 may be an anode and the second electrode EL2 may be a cathode.

In addition, referring to FIG. 5B, the light-emitting element ED-b of an embodiment may include a first electrode EL1, an electron transport region ETR, an emission layer EML, a hole transport region HTR, and a second electrode EL2, which are sequentially stacked along the third directional axis DR3. In the light-emitting element ED-b of an embodiment, the first electrode EL1 may be a cathode and the second electrode EL2 may be an anode.

That is, the first to third light-emitting elements ED-1, ED-2, and ED-3 shown in FIG. 4 may have the stack structure of FIG. 5A or FIG. 5B. Accordingly, in the first to third light-emitting elements ED-1, ED-2, and ED-3, when the first functional layer FL-B is the hole transport region HTR, the second functional layer FL-T may be the electron transport region ETR, and in the first to third light-emitting elements ED-1, ED-2, and ED-3, when the first functional layer FL-B is the electron transport region ETR, the second functional layer FL-T may be the hole transport region HTR.

The emission layers EML-B, EML-G, and EML-R including the quantum dot complexes QD-C1, QD-C2, and QD-C3 in an embodiment may exhibit excellent adhesion at an interface with the first functional layer FL-B or the second functional layer FL-T. The quantum dot complexes QD-C1, QD-C2, and QD-C3 in an embodiment may allow the emission layers EML-B, EML-G, and EML-R provided on the first functional layer FL-B to have excellent coating properties, and also allow the second functional layer FL-T provided on the emission layers EML-B, EML-G, and EML-R to have excellent coating properties.

In the light-emitting elements ED-a and ED-b in an embodiment shown in FIGS. 5A and 5B, the hole transport region HTR may include a hole injection layer (not shown) and a hole transport layer (not shown). The hole transport region HTR may have a single layer including or consisting of a single material, a single layer including or consisting of a plurality of different materials, or a multilayer structure having a plurality of layers including or consisting of a plurality of different materials from each other.

The hole transport region HTR may be formed using various methods such as a vacuum deposition method, a spin coating method, a cast method, a Langmuir-Blodgett (“LB”) method, an inkjet printing method, a laser printing method, and a laser induced thermal imaging (“LITI”) method.

The hole transport region HTR may include known hole injection materials and/or known hole transport materials. In an embodiment, The hole transport region HTR may include a phthalocyanine compound such as copper phthalocyanine, N¹,N^{1′}-([1,1′-biphenyl]-4,4′-diyl)bis(N¹-phenyl-N⁴,N⁴-di-m-tolylbenzene-1,4-diamine) (“DNTPD”), 4,4′,4″-[tris(3-methylphenyl)phenylamino]triphenylamine (m-MTDATA), 4,4′4″-tris(N,N-diphenylamino)triphenylamine (“TDATA”), 4,4′,4″-tris[N(2-naphthyl)-N-phenylamino]-triphenylamine (“2-TNATA”), poly(3,4-ethylenedioxythiophene)/poly(4-styrenesulfonate) (“PEDOT/PSS”), polyaniline/Dodecylbenzenesulfonic acid (“PANI/DBSA”), polyaniline/camphor sulfonic acid (“PANI/CSA”), polyaniline/poly(4-styrenesulfonate) (“PANI/PSS”), N,N′-di(naphthalene-1-yl)-N,N′-diphenyl-benzidine (“NPB”), triphenylamine-including or consisting of polyetherketone (“TPAPEK”), 4-isopropyl-4′-methyldiphenyliodonium tetrakis(pentafluorophenyl)borate, dipyrazino[2,3-f: 2′,3′-h]quinoxaline-2,3,6,7,10,11-hexacarbonitrile (“HATCN”), or the like, for example.

In addition, the hole transport region HTR may include carbazole-based derivatives such as N-phenyl carbazole and polyvinyl carbazole, fluorene-based derivatives, N,N′-bis(3-methylphenyl)-N,N′-diphenyl-[1,1-biphenyl]-4,4′-diamine (“TPD”), triphenylamine-based derivatives such as 4,4′,4″-tris(N-carbazolyl)triphenylamine (“TCTA”), N,N′-di(1-naphtalene-1-yl)-N,N′-diphenyl-benzidine (“NPB”), 4,4′-cyclohexylidene bis[N,N-bis(4-methylphenyl]benzenamine](“TAPC”), 4,4′-bis[N,N′-(3-tolyl)amino]-3,3′-dimethylbiphenyl (“HMTPD”), 9-(4-tert-butylphenyl)-3,6-bis(triphenylsilyl)-9H-carbazole (“CzSi”), 9-phenyl-9H-3,9′-bicarbazole (“CCP”), 1,3-bis(N-carbazolyl)benzene (“mCP”), 1,3-bis(1,8-dimethyl-9H-carbazol-9-yl)benzene (“mDCP”), or the like.

The hole transport region HTR may have a thickness of about 5 nanometers (nm) to about 1,500 nm, e.g., about 10 nm to about 500 nm. When the thickness of the hole transport region HTR satisfies the above-described range, satisfactory hole transport properties may be obtained without a substantial increase in driving voltage.

In the light-emitting elements ED-a and ED-b in an embodiment, the electron transport region ETR may include at least one of an electron transport layer (not shown) or an electron injection layer (not shown), but the inventive concept is not limited thereto.

The electron transport region ETR may have a single layer including or consisting of a single material, a single layer including or consisting of a plurality of different materials, or a multilayer structure having a plurality of layers including or consisting of a plurality of different materials from each other. In an embodiment, the electron transport region ETR may have a single layer structure of an electron injection layer or an electron transport layer, and may have a single layer structure including or consisting of an electron injection material and an electron transport material, for example. The electron transport region ETR may have a thickness of, e.g., about 20 nm to about 150 nm.

The electron transport region ETR may be formed using various methods such as a vacuum deposition method, a spin coating method, a cast method, an LB method, an inkjet printing method, a laser printing method, and an LITI method.

The electron transport region ETR may include known electron injection materials and/or known electron transport materials. In an embodiment, the electron transport region ETR may include an anthracene-based compound, for example. In an alternative embodiment, the electron transport region ETR may include, e.g., tris(8-hydroxyquinolinato)aluminum (“Alq₃”), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzimidazolyl-1-ylphenyl)-9,10-dinaphthylanthracene, 1,3,5-tri(1-phenyl-1H-benzo[d]imidazol-2-yl)benzene (“TPBi”), 2,9-dimethyl-4,7-diphenyl-1,10-phenanthroline (“BCP”), 4,7-diphenyl-1,10-phenanthroline (“Bphen”), 3-(4-biphenylyl)-4-phenyl-5-tert-butylphenyl-1,2,4-triazole (“TAZ”), 4-(naphthalen-1-yl)-3,5-diphenyl-4H-1,2,4-triazole (“NTAZ”), 2-(4-biphenylyl)-5-(4-tert-butylphenyl)-1,3,4-oxadiazole (“tBu-PBD”), bis(2-methyl-8-quinolinolato-N1,O8)-(1,1′-biphenyl-4-olato)aluminum (“BAlq”), berylliumbis(benzoquinolin-10-olate (“Bebq₂”), 9,10-di(naphthalene-2-yl)anthracene (“ADN”), 1,3-bis[3,5-di(pyridin-3-yl)phenyl]benzene (“BmPyPhB”), or any combinations thereof. In an alternative embodiment, the electron transport region ETR may include 2,9-dimethyl-4,7-diphenyl-1,10-phenanthroline (“BCP”), diphenyl(4-(triphenylsilyl)phenyl)phosphine oxide (“TSPO1”), 4,7-diphenyl-1,10-phenanthroline (“Bphen”), or the like.

Referring to FIG. 4, the first functional layer FL-B and the second functional layer FL-T may be provided as a common layer throughout the light-emitting regions PXA-B, PXA-G, and PXA-R. In an embodiment, the functional layer FL may overlap both the emission layers EML-B, EML-G, and EML-R and the pixel defining layer PDL. However, the inventive concept is not limited to this, and at least one of the first functional layer FL-B or the second functional layer FL-T overlaps the emission layers EML-B, EML-G, and EML-R, and may be patterned and provided to be disposed in a pixel opening OH.

Referring to FIG. 4, the display device DD of an embodiment includes an optical structure layer PP disposed on the display panel DP. The optical structure layer PP may include a base layer BL and a color filter layer CFL.

The base layer BL may be a member providing a base surface on which the color filter layer CFL is disposed. The base layer BL may be a glass substrate, a metal substrate, a plastic substrate, or the like. However, the inventive concept is not limited thereto, and the base layer BL may be an inorganic layer, an organic layer, or a complex material layer.

The color filter layer CFL may include filters CF-B, CF-G, and CF-R. The color filter layer CFL may include first to third filters CF-B, CF-G, and CF-R. The first to third filters CF-B, CF-G, and CF-R may be arranged to respectively correspond to the first to third light-emitting elements ED-1, ED-2, and ED-3. In an embodiment, the first filter CF-B may be a blue filter, the second filter CF-G may be a green filter, and the third filter CF-R may be a red filter, for example. The first to third filters CF-B, CF-G, and CF-R may be arranged to respectively correspond to the first to third pixel regions PXA-B, PXA-G, and PXA-R.

In addition, the plurality of filters CF-B, CF-G, and CF-R that transmit different light from each other may be disposed to overlap in corresponding to the peripheral region NPXA disposed between the light-emitting regions PXA-R, PXA-B, and PXA-G. The plurality of filters CF-B, CF-G, and CF-R may be disposed to overlap in the third direction DR3, which is the thickness direction, to separate boundaries between the adjacent light-emitting regions PXA-R, PXA-B, and PXA-G. Accordingly, the effect of blocking external light increases to serve as the same function as a black matrix. The overlapping structure of the plurality of filters CF-B, CF-G, and CF-R may serve to prevent color mixing.

The first to third filters CF-B, CF-G, and CF-R may each include a polymer photosensitive resin and a pigment or a dye. The first filter CF-B may include a blue pigment or a blue dye, the second filter CF-G may include a green pigment or a green dye, and the third filter CF-R may include a red pigment or a red dye. However, the inventive concept is not limited thereto, and the first filter CF-B may not include a pigment or a dye. The first filter CF-B may include a polymer photosensitive resin, but not include a pigment or a dye. The first filter CF-B may be transparent. The first filter CF-B may include or consist of a transparent photosensitive resin.

The color filter layer CFL may further include a buffer layer BFL. In an embodiment, the buffer layer BFL may be a protection layer protecting the first to third filters CF-B, CF-G, and CF-R, for example. The buffer layer BFL may be an inorganic material layer including at least one inorganic material among silicon nitride, silicon oxide, and silicon oxynitride. The buffer layer BFL may consist of a single layer or a plurality of layers.

In addition, the second filter CF-G and the third filter CF-R may be yellow filters. The second filter CF-G and the third filter CF-R may not be separated from each other and may be provided as a single body.

Although not shown, the color filter layer CFL may further include a light-blocking unit (not shown). The light-blocking unit may be a black matrix. The light-blocking unit may be formed including an organic light-blocking material or an inorganic light-blocking material, both including a black pigment or a black dye. The light-blocking unit may prevent light leakage, and separate boundaries between the adjacent filters CF-B, CF-G, and CF-R.

In addition, unlike what is shown in FIG. 4 or the like, the optical structure layer PP of the display device DD of an embodiment may not include the color filter layer CFL.

Emission layers of the light-emitting elements ED, ED-a, and ED-b in an embodiment described with reference to FIGS. 4 to 5B may include a quantum dot complex.

FIG. 6 is a view schematically showing an embodiment of a quantum dot complex. FIGS. 7A and 7B are each a schematic view showing an enlarged portion of a quantum dot complex. FIG. 7A shows a view enlarging area XX′ of FIG. 6, and FIG. 7B shows a view enlarging area YY′ of FIG. 6.

Referring to FIG. 6, the quantum dot complex of an embodiment may include a quantum dot MC, and a first ligand LD-C and a second ligand LD-M, which are bonded to a surface of the quantum dot. The first ligand LD-C and the second ligand LD-M may be different.

The quantum dot MC refers to a crystal of a semiconductor compound, and may include any material that may emit light of various emission wavelengths depending on the size of the crystal or the adjusted element ratio in the quantum dot MC compound. The quantum dot MC may include semiconductor nanocrystals.

The quantum dot MC may be synthesized through a wet chemical process, a metal organic chemical vapor deposition process, a molecular beam epitaxy process, or a process similar thereto. The wet chemical process is a method of mixing an organic solvent and a precursor material and then growing a quantum dot particle crystal. When the crystal grows, the organic solvent naturally serves as a dispersant coordinated to a surface of the quantum dot crystal and may control the growth of the crystal. Therefore, the wet chemical process is easier than vapor deposition methods such as metal organic chemical vapor deposition (“MOCVD”) or molecular beam epitaxy (“MBE”), and may control the growth of quantum dot particles through a low-cost process.

The quantum dot MC may be selected from a Group II-VI compound, a Group III-VI compound, a Group I-III-VI compound, a Group III-V compound, a Group III-II-V compound, a Group IV-VI compound, a Group IV element, a Group IV compound, and any combinations thereof.

The Group II-VI compound may be include a binary compound including CdSe, CdTe, CdS, ZnS, ZnSe, ZnTe, ZnO, HgS, HgSe, HgTe, MgSe, MgS, or any combinations thereof; a ternary compound including CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, or any combinations thereof; and a quaternary compound including HgZnTeS, CdZnSeS, CdZnSeTe, CdZnSTe, CdHgSeS, CdHgSeTe, CdHgSTe, HgZnSeS, HgZnSeTe, or any combinations thereof.

The Group III-VI compound may include a binary compound such as In₂S₃ and In₂Se₃, a ternary compound such as InGaS₃ and InGaSe₃, or any combination thereof.

The Group I-III-VI compound may be selected from a ternary compound including AgInS, AgInS₂, CuInS, CuInS₂, AgGaS₂, CuGaS₂ CuGaO₂, AgGaO₂, AgAlO₂, or any combinations thereof, or a quaternary compound such as AgInGaS₂ and CuInGaS₂.

The Group III-V compound may include a binary compound including GaN, GaP, GaAs, GaSb, AlN, AlP, AlAs, AlSb, InN, InP, InAs, InSb, or any combinations thereof, a ternary compound including GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, or any combinations thereof, and a quaternary compound including GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, or any combinations thereof. In an embodiment, the Group III-V compound may further include a Group II metal. In an embodiment, InZnP or the like may be selected as a Group III-II-V compound.

The Group IV-VI compound may include a binary compound including SnS, SnSe, SnTe, PbS, PbSe, PbTe, or any combinations thereof, a ternary compound including SnSeS, SnSeTe, SnSTe, PbSeS, PbSeTe, PbSTe, SnPbS, SnPbSe, SnPbTe, or any combinations thereof, and a quaternary compound including SnPbSSe, SnPbSeTe, SnPbSTe, or any combinations thereof. The Group IV element may include Si, Ge, or any combinations thereof. The Group IV compound may be a binary compound including SiC, SiGe, or any combinations thereof.

In this case, the binary compound, the ternary compound, or the quaternary compound may be in particles having a uniform concentration distribution, or may be in the same particles having a partially different concentration distribution. Additionally, in an embodiment, the quantum dot MC may have a core-shell structure including a core CR and a shell SL. The core-shell structure may have a concentration gradient in which the concentration of an element present in the shell SL becomes lower towards the core CR.

The quantum dot MC in an embodiment having the core-shell structure may include a core CR including or consisting of the above-described nanocrystals and a shell SL surrounding the core and including or consisting of nanocrystals. The shell SL of the quantum dot may serve as a protection layer to prevent the chemical deformation of the core CR so as to keep semiconductor properties, and/or a charging layer to impart electrophoresis properties to the quantum dot. The shell SL may be a single layer or multiple layers. In embodiments, the shell SL of the quantum dot may be a metal or non-metal oxide, a semiconductor compound, or any combinations thereof.

The shell SL may include a different material from the core CR. In an embodiment, the core CR may include a first semiconductor nanocrystal, and the shell SL may include a second semiconductor nanocrystal different from the first semiconductor nanocrystal, for example. In an alternative embodiment, the shell SL may include metal or non-metal oxide. The shell SL may include metal or non-metal oxide, a semiconductor compound, or any combinations thereof.

The shell SL may include or consist of a single material, but may be formed to have a concentration gradient. In an embodiment, the shell SL has a concentration gradient in which the concentration of the second semiconductor nanocrystals in the shell SL decreases and the concentration of the first semiconductor nanocrystals included in the core CR increases towards the core CR, for example. FIG. 5A shows that the shell SL has a single-layer structure in an embodiment, the inventive concept is not limited thereto, and the shell SL may have a plurality of layer structures including or consisting of different materials from each other.

In an embodiment, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, or a ternary compound such as MgAl₂O₄, CoFe₂O₄, NiFe₂O₄, and CoMn₂O₄, for example, but the inventive concept is not limited thereto.

In addition, the semiconductor compound may be CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or the like, for example, but the inventive concept is not limited thereto.

The quantum dot MC may have a full width of half maximum (“FWHM”) of a light emission wavelength spectrum of about 45 nm or less, and color purity or color reproducibility may be enhanced in the above ranges. In addition, light emitted through the quantum dot is emitted in all directions, and thus a wide viewing angle may be improved.

In addition, the form of the quantum dots MC is not particularly limited as long as it is a form commonly used in the art, but more specifically, quantum dots in the form of spherical, pyramidal, multi-arm, or cubic nanoparticles, nanotubes, nanowires, nanofibers, nanoplatelets, or the like may be used.

Te energy band gap of the quantum dot MC may be regulated by adjusting the size or the element ratio in the quantum dot MC compound, and accordingly, the emission layer EML (FIGS. 5A and 5B) including a quantum dot complex QD-C formed including the quantum dot MC may emit light in various wavelength ranges. Therefore, by the quantum dot MC of different sizes as described above or by the quantum dot complex QD-C with different element ratios in the quantum dot MC compound, a light-emitting element emitting light of various wavelengths may be obtained. Specifically, by regulating the size of the quantum dot MC or the element ratio in the quantum dot MC compound, the quantum dot complex QD-C may have various emission colors such as blue, red, and green. In addition, the quantum dot complexes QD-C may emit white light by combining light of various colors. The smaller the particle size of the quantum dot MC, the more likely the quantum dot complex QD-C may emit light in a short wavelength range, for example. In an embodiment, in the quantum dot MC having the same core, the particle size of the quantum dot emitting green light may be smaller than the particle size of the quantum dot emitting red light. In addition, in the quantum dot MC having the same core, the particle size of the quantum dot emitting blue light may be smaller than the particle size of the quantum dot emitting green light. However, the inventive concept is not limited thereto, and even in the quantum dot MC having the same core, the particle size may be adjusted according forming-materials and thickness of a shell.

When the quantum dot complex QD-C has various light emission colors such as blue, red, green, or the like, the quantum dot MC having different light emission colors may have different core CR materials.

In an embodiment, the core CR may include a Group III-V compound or a Group I-III-VI compound. In an embodiment, the core CR may include InP or AgInGaS, for example. The quantum dot MC of an embodiment includes the core CR including or consisting of a Group III-V compound or a Group I-III-VI compound, and may thus have a relatively high blue light absorption rate.

In an embodiment, the quantum dot MC may be a non-Cd-based quantum dot. That is, the quantum dot MC may not include cadmium (Cd). The quantum dot MC may include two or more elements selected from Group II and Group VI elements, excluding Cd. The quantum dot MC may be formed by including two, three, or four elements selected from Group II and Group VI elements, excluding Cd. In an embodiment, in an embodiment, the quantum dot MC may include ZnSeTe, for example.

The quantum dot complex QD-C of an embodiment may absorb light between about 300 nm and about 500 nm. In an embodiment, the quantum dot complex QD-C of an embodiment may absorb light in the range of about 300 nm to about 450 nm, for example. The quantum dot complex QD-C may absorb light in the above-described wavelength ranges and emit blue light, green light, or red light.

In an embodiment, the quantum dot MC may have a diameter of about 1 nm to about 10 nm. When the quantum dot MC satisfies the average particle diameter ranges described above, a characteristic behavior as the quantum dot MC and excellent dispersibility as well may be achieved. In addition, when the average particle diameter of the quantum dot MC is variously selected within the ranges as described above, the emission wavelength of the quantum dot MC and/or the semiconductor properties of the quantum dot MC may be variously changed.

The quantum dot complex QD-C of an embodiment may include a quantum dot MC, a first ligand LD-C bonded to a surface of the quantum dot MC, and a second ligand LD-M boned to a surface of the quantum dot MC and different from the first ligand LD-C. The quantum dot complex QD-C of an embodiment includes a second ligand LD-M having two different functional groups, and may thus exhibit modified surface properties compared to a case including the first ligand LD-C alone. In an embodiment, the quantum dot MC may include a core CR and a shell SL, and the first ligand LD-C and the second ligand LD-M may be bonded to a surface of the shell SL.

Referring to FIGS. 6 and 7A, the first ligand LD-C may include a thiol group at one end adjacent to the surface of the quantum dot MC. The first ligand LD-C may include a first head portion HP1 bonded to the surface of the quantum dot MC and a first tail portion TP1 extending from the first head portion HP1. The first head portion HP1 may be a portion including or consisting of a thiol group, and the first tail portion TP1 may be a portion including or consisting of an alkyl group. The first tail portion TP1 may correspond to a substituted or unsubstituted alkyl group. The first tail portion TP1 may include an alkyl group having 2 carbon atoms to 20 carbon atoms.

Referring to FIGS. 6 and 7B, the second ligand LD-M may include a thiol group at one end adjacent to the surface of the quantum dot MC, and a carboxyl group at an opposite end spaced from the surface of the quantum dot MC. The second ligand LD-M may include a plurality of functional groups having different polarities. The second ligand LD-M may include two different functional groups. The second ligand may be an amphiphilic material.

The second ligand LD-M may include a second head portion HP2 bonded to the surface of the quantum dot MC, an end portion EP spaced apart from the surface of the quantum dot MC, and a second tail portion TP2 disposed between the second head portion HP2 and the end portion EP. The second head portion HP2 may be a portion including or consisting of a thiol group, and the second tail portion TP2 may be a portion including or consisting of an alkyl group. The second tail portion TP2 may correspond to a substituted or unsubstituted alkyl group. The second tail portion TP2 may include a substituted or unsubstituted alkyl group having 2 carbon atoms to 20 carbon atoms. The end portion EP may be a portion including or consisting of a carboxyl group. The end portion EP is exposed to the outside of the quantum dot complex QD-C and may thus control the surface properties of the quantum dot complex QD-C. The quantum dot complex QD-C including or consisting of a second ligand LD-M having an acidic group such as a carboxyl group may have increased polarity on the surface.

The first ligand LD-C and the second ligand LD-M are monodentate ligands in which each of the corresponding head portions HP1 and HP2 includes or consists of one functional group to be bonded to the surface of the quantum dot MC. That is, each of the first head portion HP1 and the second head portion HP2 may include one functional group for binding to the surface of the quantum dot MC. However, the inventive concept is not limited thereto, and each of the first ligand LD-C and the second ligand LD-M may be a bidentate ligand in which each of the corresponding head portions HP1 and HP2 includes or consists of two functional groups to be bonded to the surface of quantum dot MC. The head portions HP1 and HP2 include functional groups for binding to the surface of the quantum dot MC, and thus the ligands LD-C and LD-M may effectively be bonded to the quantum dot MC. In an embodiment, the first head portion HP1 and the second head portion HP2 may include a thiol group.

The first ligand LD-C and the second ligand LD-M may each include the tail portions TP1 and TP2, and one end of the tail portions TP1 and TP2 may be connected to the head portions HP1 and HP2. In an embodiment, one end of the first tail portion TP1 of the first ligand LD-C may be connected to the first head portion HP1, and an opposite end may be exposed to the outside of the quantum dot complex QD-C. In addition, in an embodiment, one end of the second tail portion TP2 of the second ligand LD-M may be connected to the second head portion HP2, and an opposite end may be connected to the end portion EP exposed to the outside of the quantum dot complex QD-C.

In an embodiment, the second ligand LD-M may be represented by Formula 1 below.

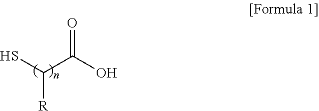

In Formula 1, n is an integer of 1 to 20, and R is a hydrogen atom, a deuterium atom, a substituted or unsubstituted thiol group, a substituted or unsubstituted amine group, or a substituted or unsubstituted alkyl group having 1 to 10 carbon atoms.

The second ligand LD-M may be represented by any one among the following LD1 to LD4. The quantum dot complex QD-C in an embodiment may include at least one of the following LD1 to LD4 as a second ligand LD-M.

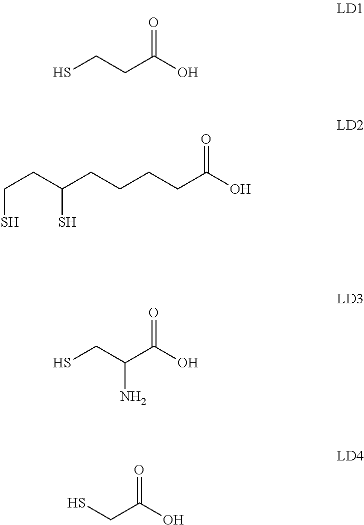 [SMILES: O=C(O)CCS ; O=C(O)CCCCC(S)CCS ; NC(CS)C(=O)O ; O=C(O)CS]

LD1 may be named 3-mercaptopropanoic acid (“MPA”), LD2 may be named dihydrolipoic acid (“DHLA”), LD3 may be named cysteine (“CYS”), and LD4 may be named thioglycolic acid (“TGA”).

That is, LD1 to LD4 may each include a thiol group at one end and a carboxyl group at an opposite end.

In the quantum dot complex QD-C in an embodiment, the first ligand LD-C and the second ligand LD-M may each be bonded to the surface of the quantum dot MC. In the quantum dot complex QD-C in an embodiment, the first ligand LD-C may be included in a greater weight ratio than that of the second ligand LD-M. In the quantum dot complex QD-C of an embodiment, the first ligand LD-C and the second ligand LD-M may be in a weight ratio of about 99:1 to about 50:50. In an embodiment, in the quantum dot complex QD-C, the first ligand LD-C and the second ligand LD-M may be in a weight ratio of about 99:1 to about 90:10, for example. Specifically, in the quantum dot complex QD-C, the first ligand LD-C and the second ligand LD-M may be in a weight ratio of about 98:2 to about 90:10.

The quantum dot complex QD-C of an embodiment includes or consists of the second ligands LD-M in an amount of at least 1/100 of the total weight of the ligand, and may thus have modified surface properties. In addition, the quantum dot complex QD-C of an embodiment includes or consists of the second ligands LD-M in an amount of less than or equal to 50/100 of the total weight of the ligand, and may thus have excellent surface modification characteristics and maintain satisfactory optical properties and compatibility with nonpolar materials. In an embodiment, the quantum dot complex QD-C of an embodiment includes or consists of the second ligands LD-M in an amount of 2 to 10/100 of the total weight of the ligand, and may thus exhibit excellent surface modification characteristics properties, satisfactory optical properties, and excellent compatibility with nonpolar materials even with a relatively small weight ratio of the second ligand, for example.

In the second ligand LD-M in an embodiment, the thiol group may be a portion adjacent to the quantum dot MC, and the carboxyl group may be a portion spaced apart from the quantum dot MC. The quantum dot complex QD-C may exhibit polar surface properties due to the carboxyl group. Accordingly, the quantum dot complex QD-C has increased compatibility with polar solvents such as alcohols or ethers, and a layer including or consisting of the quantum dot complex QD-C and layers adjacent thereto may each exhibit excellent coating properties. Accordingly, the interface characteristics between the layer formed including the quantum dot complex QD-C and the adjacent functional layer FL (FIG. 4) are improved.

In an embodiment, the light-emitting element ED-a of an embodiment shown in FIG. 5A described above may include the quantum dot complex QD-C in the emission layer EML, for example. After forming the emission layer EML including the quantum dot complex QD-C of an embodiment, an electron transport region ETR (FIG. 5A) may be provided. When manufacturing the light-emitting element ED-a in an embodiment, the electron transport region ETR may be directly formed on the emission layer EML. The electron transport region ETR may be formed from a common layer composition including electron transport materials and organic solvents. The common layer composition is provided on the emission layer EML, and the common layer composition may have excellent wetting properties with respect to the emission layer EML due to the polar properties of the surface of the quantum dot complex QD-C. A contact angle of an organic solvent with respect to the emission layer EML including the quantum dot complex QD-C may be 15°. In an embodiment, the common layer composition may include DGtBE and TPGBE as the organic solvent, for example. However, the type of organic solvent is not limited to thereto. The solvents DGtBE and TPGBE are as follows.

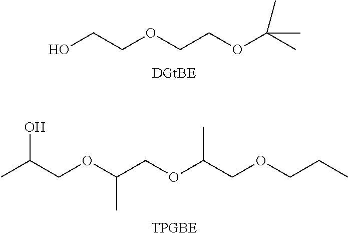

The quantum dot complex QD-C of an embodiment includes the second ligand LD-M including or consisting of a carboxyl group at the end portion EP, and may thus have increased compatibility with the organic solvent of the common layer composition. The contact angle of the organic solvent is as relatively low as 15° or less, and accordingly, the functional layer FL formed from the common layer composition may exhibit excellent wetting properties and adhesion to the emission layer EML.

Accordingly, an interface between the emission layer EML and the electron transport region ETR has excellent adhesion, and the light-emitting element ED-b may exhibit improved reliability due to excellent coating properties.

The interface properties between the electron transport region ETR and the emission layer EML are described in an embodiment, and the modified surface properties of the quantum dot complex QD-C may also allow other functional layers adjacent to the layer including or consisting of the quantum dot complex QD-C to exhibit excellent coating properties and excellent interface properties. Accordingly, the light-emitting elements ED-a and ED-b (FIGS. 5A and 5B) of an embodiment may have improved reliability due to excellent adhesion between the layer including or consisting of the quantum dot complex QD-C of an embodiment and the neighboring layers thereof.

In addition, the quantum dot complex QD-C of an embodiment has relatively high compatibility with polar solvents due to the modified polar surface properties, and may thus be mixed with the polar solvents and used. The combination of the polar solvent and the quantum dot complex QD-C may be used as a composition for printing. The quantum dot complex QD-C may be mixed with a solvent and applied through an inkjet printing process. The quantum dot complex QD-C of an embodiment may be well applied through a nozzle of an inkjet printing device without being separated from the solvent. When the quantum dot complex of an embodiment is provided through an inkjet printing process, the emission layer may exhibit excellent thin film characteristics, and the processability of the emission layer manufacturing process may be improved.

Table 1 below shows the contact angle characteristics of the organic solvent for coating layers including or consisting of the quantum dot complexes of Comparative Example and Examples. The contact angle evaluated in Table 1 is a contact angle measured when as an organic solvent used in the common layer composition forming the functional layer, the organic solvent in which DGtBE and TPGBE are mixed at a weight ratio of 7:3 is applied onto the layer including or consisting of the quantum dot complex. That is, the contact angle in Table 1 corresponds to the contact angle of the organic solvent with respect to the layer including or consisting of the quantum dot complex.

In Comparative Example evaluated in Table 1, only the first ligand was bonded to the surface of the quantum dot, and in each of Examples 1 to 4, the first ligand and the second ligand were bonded to the surface of the quantum dot at the indicated weight ratio. The first ligand used in Comparative Example and Examples corresponds to dodecanethiol (“DDT”), and the second ligand used in Examples corresponds to 3-mercaptopropanoic acid (“MPA”), which is LD1.

TABLE 1

| | Weight ratio (1st ligand:2nd | Contact |
|---|---|---|
| Item | ligand) | angle (°) |
| Comparative Example | 100:0 | 22.4 |
| Example 1 | 99:1 | 14.8 |
| Example 2 | 98:2 | 10.8 |
| Example 3 | 95:5 | 9.1 |
| Example 4 | 90:10 | 10.9 |

Referring to the results in Table 1, it is seen that the contact angle of the organic solvent is significantly lower in Examples than in Comparative Example. Compared to Comparative Example, which including layers including or consisting of a quantum dot complex to which only the first ligand is bonded, with no inclusion of the second ligand, it is seen that Example in which the weight ratio of the second ligand to the total weight (100) of the ligand is 1 or greater, the contact angle of the organic solvent is reduced by more than 6°. That is, in a quantum dot complex including or consisting of a second ligand having multifunctional groups, one of the multifunctional groups has polarity, and accordingly the quantum dot complex including or consisting of the second ligand has greater compatibility with organic solvents than the quantum dot complex including or consisting of the first ligand alone.

As the weight ratio of the second ligand to the total weight of the ligand increases, the contact angle of the organic solvent with respect to the layer including or consisting of the quantum dot complex may decrease. When the weight ratio of the second ligand to the total weight of the ligand increases above a predetermined level, the extent of reduction in the contact angle of the organic solvent with respect to the layer including or consisting of the quantum dot complex may be reduced, or the contact angle of the organic solvent may remain in the range of a predetermined level. In an embodiment, referring to Table 1, it is seen that when the weight ratio of the second ligand to the total weight of the ligand increases from 5 to 10, the changes in the contact angle of the organic solvent are not significant and the contact angle remains in a similar range, for example.

As in Examples, when a common layer composition including or consisting of an organic solvent is provided on a layer formed including a quantum dot complex to which both the first ligand and the second ligand are bonded, the common layer composition has increased wetting properties. Accordingly, the common layer composition may be uniformly applied on the layer including or consisting of the quantum dot complex, and the interface characteristics between the layer including or consisting of the quantum dot complex and the functional layer adjacent thereto may be improved.

Table 2 below shows the luminescence characteristics of the quantum dot complex. Table 2 shows evaluation results of the wavelength (λ_{PL,max}) indicating the maximum emission at an emission peak and the FWHM of the emission peak in Comparative Example and Examples.

The composition of the quantum dot complex used in Comparative Example and Examples is the same as that of Comparative Example and Examples used in the contact angle evaluation described in Table 1. That is, Comparative Example is for quantum dot complexes in which only the first ligand is bonded to a quantum dot surface, and each of Examples 1 to 4 are for quantum dot complexes in which the first ligand and the second ligand are bonded to a quantum dot surface at the given weight ratio. The first ligand used in Comparative Example and Examples corresponds to DDT, and the second ligand used in Examples corresponds to MPA, which is LD1.

In Table 2, a solution state and a film state were evaluated separately. The solution state corresponds to a case where the quantum dot complex is provided in a liquid state, and the film state corresponds to a case where the quantum dot complex is provided to form a single layer in a fixed state.

TABLE 2

| | Weight ratio | Solution state | | Film state | |
|---|---|---|---|---|---|
| | (1st ligand:2nd | λ_{PL, max} | FWHM | λ_{PL, max} | FWHM |
| Item | ligand) | (nm) | (nm) | (nm) | (nm) |
| Comparative | 100:0 | 445 | 40 | 447 | 41 |
| Example | | | | | |
| Example 1 | 99:1 | 445 | 38 | 449 | 39 |
| Example 2 | 98:2 | 446 | 39 | 450 | 39 |
| Example 3 | 95:5 | 447 | 40 | 461 | 38 |
| Example 4 | 90:10 | 443 | 38 | 447 | 40 |

Referring to the results in Table 2, the wavelength (λ_{PL,max}) indicating the maximum emission at the emission peak and the FWHM of the emission peak showed similar values for Comparative Example and Examples in each of the solution condition and the film condition. That is, it is seen that Examples exhibit similar luminescence properties to Comparative Example in each of the solution state and film state. That is, even when it is believed that the second ligand is introduced, the luminescence properties of the quantum dot complex may remain at a similar level to that of typical quantum dot complexes in which a polar functional group is not introduced. In addition, the quantum dot complex in an embodiment may exhibit optical properties similar to those of the typical quantum dot composites. FIGS. 8A and 8B are each a view showing the results of evaluating the luminescence characteristics of Comparative Example and Examples. FIG. 8A shows the absorbance and normalized PL peaks of Comparative Example and Examples 1 to 4 in the solution state. In addition, FIG. 8B shows the normalized emission peaks of Comparative Example and Examples 1 to 4 in the film state. Comparative Example and Examples 1 to 4 shown in FIG. 8A correspond to the solution states of Comparative Example and Examples 1 to 4 in Table 2 described above, respectively, and Comparative Example and Examples 1 to 4 shown in FIG. 8B correspond to the film states of Comparative Example and Examples 1 to 4 in Table 2 described above, respectively.

Referring to FIG. 8A, Comparative Example and Examples 1 to 4 show similar absorbance and emission peaks. Comparative Example and Examples 1 to 4 showed absorbance characteristics of absorbing light between 300 nm and 450 nm. That is, it is seen that Examples including the quantum dot complex in an embodiment including both the first ligand and the second ligand exhibit similar optical properties to Comparative Example including only the first ligand. In addition, it is seen that the absorbance remains similar even with an increase in the ratio of the second ligand, and accordingly, the second ligand, which is an amphipathic ligand, improves the surface properties of the quantum dot complex while minimizing the impact on the optical properties of the quantum dot complex.

In addition, it is seen that the luminescence properties of Comparative Example and Examples are similar in the normalized emission peaks shown in FIG. 8A. The shapes of the emission peaks and maximum emission wavelengths of Comparative Example and Examples were also similar. In addition, it is seen that the emission peak characteristics remain similar even with the increased ratio of the second ligand. Therefore, considering Table 2 and FIG. 8A described above, it is seen that the quantum dot complex in an embodiment exhibits satisfactory optical and luminous properties in the solution state.

Referring to FIG. 8B, it is seen that Comparative Example and Examples 1 to 4 exhibit similar emission peak characteristics even in the film state. That is, even in the film state, the shapes of the emission peaks of Comparative Example and Examples were similar. Although there are some differences in the maximum emission wavelength between Comparative Example and Examples, the difference in the maximum emission wavelength is within 15 nm, indicating that Comparative Example and Examples maintain similar luminous properties. In addition, it is seen that the emission peak characteristics of Examples remain similar even with the increased ratio of the second ligand. Therefore, considering Table 2 and FIG. 8B described above, it is seen that the quantum dot complex in an embodiment exhibits satisfactory optical and luminous properties even in the film state.

Considering Table 2 and FIGS. 8A and 8B, it is seen that the optical properties and luminous properties of the quantum dot complex remain at a similar level depending on the presence or absence of the second ligand or the content of the second ligand. That is, Examples further including the second ligand exhibits similar optical and luminous properties to those of Comparative Example, and accordingly, the optical properties and emission wavelength characteristics of the light-emitting element in an embodiment may remain at a satisfactory level with the introduction of the second ligand. In addition, a display device in an embodiment including the quantum dot complex in an embodiment may also be expected to maintain an excellent display quality level in terms of optical properties and emission wavelength characteristics.

The quantum dot complex in an embodiment includes both the first ligand having an alkyl group and the second ligand having a carboxyl group at one end spaced apart from the surface of the quantum dot, and may thus have improved surface properties. Accordingly, the quantum dot complex has increased wetting properties with neighboring coating layers using polar solvents, or the like, and may thus exhibit excellent adhesion at an interface with neighboring layers. That is, the quantum dot complex in an embodiment maintains satisfactory optical and luminous properties and also has relatively high wetting properties with neighboring materials, thereby exhibiting excellent interface properties and excellent reliability accordingly. In addition, the quantum dot complex in an embodiment has improved surface properties to have improved compatibility with polar solvents, or the like, and may thus be mixed with the solvent to be easily used in an inkjet printing process. Accordingly, the quantum dot complex of an embodiment may exhibit excellent coating properties when applied to an inkjet printing process.

The light-emitting element in an embodiment includes a quantum dot complex including both a first ligand having an alkyl group and a second ligand having a carboxyl group at one end spaced apart from a quantum dot surface in an emission layer, and may thus maintain satisfactory optical and luminous properties and have excellent adhesion to adjacent functional layers, thereby exhibiting improved device element. In addition, the display device of an embodiment includes a light-emitting element including a quantum dot complex including both a first ligand having an alkyl group in a display element layer and a second ligand having a carboxyl group at one end spaced apart from a quantum dot surface, and may thus exhibit excellent display quality and improved reliability.

A quantum dot complex of an embodiment includes two different types of ligands, and may thus exhibit excellent wetting properties of adjacent layer materials without changes in optical properties.

A light-emitting element of an embodiment includes a quantum dot complex in which two types of ligands are bonded to an emission layer, and may thus have excellent coating properties of the emission layer and excellent interface properties between the emission layer and neighboring functional layer to provide satisfactory optical properties and excellent element quality.

A display device of an embodiment includes a light-emitting element including a quantum dot complex in which two types of ligands are bonded to an emission layer, and may thus provide excellent display quality.

Although the disclosure has been described with reference to a preferred embodiment of the inventive concept, it will be understood that the inventive concept should not be limited to these preferred embodiments but various changes and modifications may be made by those skilled in the art without departing from the spirit and scope of the disclosure.

Accordingly, the technical scope of the inventive concept is not intended to be limited to the contents set forth in the detailed description of the specification, but is intended to be defined by the appended claims.

What is claimed is:

1. A quantum dot complex comprising:
a quantum dot;
a first ligand bonded to a surface of the quantum dot and including a thiol group at an end of the first ligand; and
a second ligand different from the first ligand, bonded to a surface of the quantum dot, and including a thiol group at an end of the second ligand and a carboxyl group at an opposite end of the second ligand.

2. The quantum dot complex of claim 1, wherein the first ligand comprises a first head portion including a thiol group, and a first tail portion extending from the first head portion and including an alkyl group.

3. The quantum dot complex of claim 2, wherein the first tail portion comprises an alkyl group having 2 carbon atoms to 20 carbon atoms.

4. The quantum dot complex of claim 1, wherein the second ligand comprises a second head portion including a thiol group, an end portion spaced apart from the surface of the quantum dot and including a carboxyl group, and a second tail portion disposed between the second head portion and the end portion.

5. The quantum dot complex of claim 1, wherein the second ligand is represented by Formula 1 below: 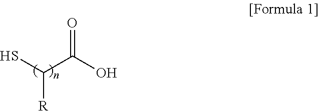
wherein in Formula 1 above,
n is an integer of 1 to 20, and
R is a hydrogen atom, a deuterium atom, a substituted or unsubstituted thiol group, a substituted or unsubstituted amine group, or a substituted or unsubstituted alkyl group having 1 carbon atom to 10 carbon atoms.

6. The quantum dot complex of claim 1, wherein the second ligand comprises at least one of compounds LD1 to LD4 below:

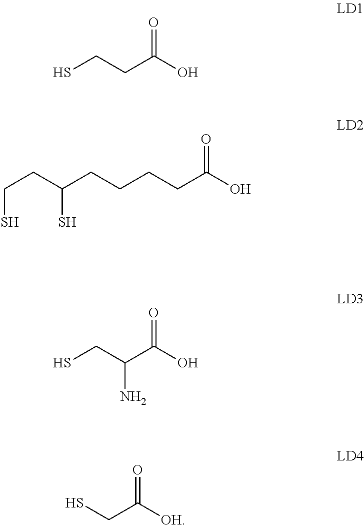 [SMILES: O=C(O)CCS ; O=C(O)CCCCC(S)CCS ; NC(CS)C(=O)O ; O=C(O)CS]

7. The quantum dot complex of claim 1, wherein the first ligand and the second ligand are at a weight ratio of about 99:1 to about 50:50.

8. The quantum dot complex of claim 1, wherein the quantum dot comprises a core and a shell surrounding the core, and
the first ligand and the second ligand are each bonded to a surface of the shell.

9. The quantum dot complex of claim 8, wherein the core comprises a first semiconductor nanocrystal, and the shell comprises a second semiconductor nanocrystal different from the first semiconductor nanocrystal, and
the first semiconductor nanocrystal and the second semiconductor nanocrystal each include at least one of a Group II-VI compound, a Group III-VI compound, a Group I-III-VI compound, a Group III-V compound, a Group III-II-V compound, a Group IV-VI compound, a Group IV element, and a Group IV compound.

10. The quantum dot complex of claim 1, wherein the quantum dot comprises two or more elements selected from Group II and Group VI elements, excluding Cd.

11. The quantum dot complex of claim 10, wherein the quantum dot comprises ZnSeTe.

12. The quantum dot complex of claim 1, wherein the quantum dot complex absorbs light in a range of about 300 nanometers to about 450 nanometers.

13. A light-emitting element comprising:
a first electrode;
a second electrode facing the first electrode;
an emission layer disposed between the first electrode and the second electrode and including a quantum dot complex, the quantum dot complex including:
a quantum dot;
a first ligand bonded to a surface of the quantum dot and including a thiol group at an end of the first ligand; and
a second ligand different from the first ligand, bonded to a surface of the quantum dot, and including a thiol group at an end of the second ligand and a carboxyl group at an opposite end of the second ligand; and
a functional layer disposed at least one of between the emission layer and the first electrode or between the emission layer and the second electrode.

14. The light-emitting element of claim 13, wherein the first ligand comprises a first head portion including a thiol group, and a first tail portion extending from the first head portion and including an alkyl group, and
the second ligand comprises a second head portion including a thiol group, an end portion spaced apart from the surface of the quantum dot and including a carboxyl group, and a second tail portion disposed between the second head portion and the end portion.

15. The light-emitting element of claim 13, wherein the second ligand is represented by Formula 1 below: 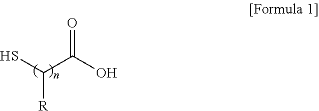
wherein in Formula 1 above,
n is an integer of 1 to 20, and
R is a hydrogen atom, a deuterium atom, a substituted or unsubstituted thiol group, a substituted or unsubstituted amine group, or a substituted or unsubstituted alkyl group having 1 carbon atom to 10 carbon atoms.

16. The light-emitting element of claim 13, wherein the second ligand comprises at least one of compounds LD1 to LD4 below:

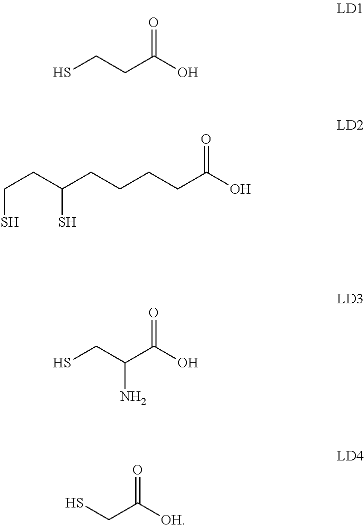 [SMILES: O=C(O)CCS ; O=C(O)CCCCC(S)CCS ; NC(CS)C(=O)O ; O=C(O)CS]

17. The light-emitting element of claim 13, wherein the functional layer comprises:
a first functional layer disposed between the first electrode and the emission layer; and
a second functional layer disposed between the emission layer and the second electrode, and
one of the first functional layer and the second functional layer is a hole transport region, and a remaining one of the first functional layer and the second functional layer is an electron transport region.

18. The light-emitting element of claim 13, wherein the functional layer comprises a hole transport region disposed below the emission layer, and an electron transport region disposed above the emission layer,
the electron transport region is formed from a common layer composition including an electron transport material and an organic solvent, and
a contact angle of the organic solvent with respect to the emission layer is 15° or less.

19. A display device comprising:
a circuit layer; and
a display element layer disposed on the circuit layer and including a light-emitting element and a pixel defining layer in which a pixel opening is defined, the light-emitting element including:
a first electrode;
a second electrode facing the first electrode;
an emission layer disposed between the first electrode and the second electrode and including a quantum dot complex, the quantum dot complex including:
a quantum dot;
a first ligand bonded to a surface of the quantum dot and including a thiol group at an end of the first ligand; and
a second ligand different from the first ligand, bonded to a surface of the quantum dot, and including a thiol group at an end of the second ligand and a carboxyl group at an opposite end of the second ligand; and
a functional layer disposed at least one of between the emission layer and the first electrode or between the emission layer and the second electrode.

20. The display device of claim 19, wherein the first ligand comprises a first head portion including a thiol group, and a first tail portion extending from the first head portion and including an alkyl group, and
the second ligand comprises a second head portion including a thiol group, an end portion spaced apart from the surface of the quantum dot and including a carboxyl group, and a second tail portion disposed between the second head portion and the end portion.

21. The display device of claim 19, wherein the second ligand is represented by Formula 1 below: 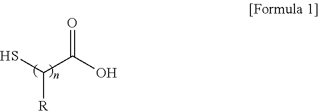
wherein in Formula 1 above,
n is an integer of 1 to 20, and
R is a hydrogen atom, a deuterium atom, a substituted or unsubstituted thiol group, a substituted or unsubstituted amine group, or a substituted or unsubstituted alkyl group having 1 carbon atom to 10 carbon atoms.

22. The display device of claim 19, wherein the second ligand comprises at least one of compounds LD1 to LD4 below:

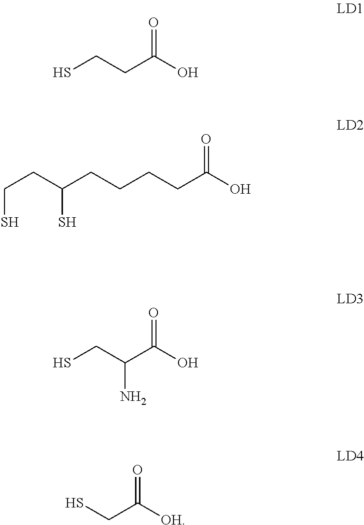 [SMILES: O=C(O)CCS ; O=C(O)CCCCC(S)CCS ; NC(CS)C(=O)O ; O=C(O)CS]

23. The display device of claim 19, wherein the functional layer comprises:
a first functional layer disposed between the first electrode and the emission layer; and
a second functional layer disposed between the emission layer and the second electrode, and
one of the first functional layer and the second functional layer is a hole transport region, and a remaining one of the first functional layer and the second functional layer is an electron transport region.

24. The display device of claim 19, wherein the emission layer is disposed in the pixel opening, and
the functional layer is a common layer overlapping the emission layer and the pixel defining layer.

25. The display device of claim 19, wherein the light-emitting element comprises a first light-emitting element including a first emission layer which emits blue light, a second light-emitting element including a second emission layer which emits green light, and a third light-emitting element including a third emission layer which emits red light, and
at least one of the first emission layer, the second emission layer, or the third emission layer comprises the quantum dot complex.
